(19) United States
(12) Patent Application Publication
(10) Pub. No.: US 2025/0301605 A1
(43) Pub. Date: Sep. 25, 2025

(54) HYBRID CHILLER AND AIR HANDLER FOR DATA CENTER

(71) Applicant: Integra Mission Critical, LLC, Dallas, TX (US)

(72) Inventors: Walter Paul Mecozzi, Edmond, OK (US); Christopher Fulton, Tobermory (CA); John Kolar, Clearwater, FL (US)

(21) Appl. No.: 19/084,662

(22) Filed: Mar. 19, 2025

Related U.S. Application Data
(60) Provisional application No. 63/567,403, filed on Mar. 19, 2024.

(51) Int. Cl. H05K 7/20

(52) U.S. Cl. CPC H05K 7/20354; H05K 7/20318; H05K 7/20827

(57) ABSTRACT

Methods and systems for combination hybrid chiller and air handler for use with data centers. A method to control capacity of two chillers in part load conditions includes forming a cascade system by connecting a first chiller and a second chiller in series. The first chiller includes a first compressor and the second chiller includes a second compressor. The method further includes modulating a capacity of the first chiller, a capacity of the second chiller, or both to control a required supply fluid temperature. In another embodiment, a method to increase a supply cooling fluid temperature of a cascade chiller system close coupled to air handlers includes monitoring positions of control valves on coils of air handlers close coupled connected to the cascade chiller system and increasing a supply cooling fluid temperature of the cascade chiller system as a function of an opening of at least one of the control valves.

### CROSS-REFERENCE TO RELATED APPLICATIONS AND CLAIM OF PRIORITY

The present application claims priority to U.S. Provisional Patent Application No. 63/567,403, filed on Mar. 19, 2024, which is hereby incorporated by reference in its entirety.

### TECHNICAL FIELD

Embodiments of the present disclosure relate to data centers and, in particular, to a combination hybrid chiller and air handler for use with data centers.

### BACKGROUND

Data center technology is currently in transition from air cooling techniques to liquid cooling techniques. The transition is occurring at an indeterminant rate, thus creating risk and requiring flexibility. Currently, operating temperatures are widely different among competing liquid cooling options. Also, increasing ambient temperatures are demanding increased operating range for cooling. Moreover, space is usually a premium resource in data center design. This requires careful consideration for chiller deployment, which requires spacing for airflow. In addition, principles of modularity for speed of deployment and economization at all operating conditions is important to take into consideration.

### SUMMARY

The present disclosure relates generally to wireless communication systems and, more specifically, the present disclosure relates to a system and method for non-uniform discrete envelope tracking.

In one embodiment, a system is provided. The system includes two or more chillers piped in series to cool a process cooling fluid. Each chiller includes a valve to direct a process cooling fluid to the chiller or to an air cooled fluid cooler with an outlet of the chiller and an outlet of the air cooled fluid cooler joined together.

In another embodiment, a method to control capacity of two chillers in part load conditions is provided. The method includes forming a cascade system by connecting a first chiller and a second chiller in series. The first chiller includes a first compressor and the second chiller includes a second compressor. The method further includes modulating a capacity of the first chiller, a capacity of the second chiller, or both to control a required supply fluid temperature.

In yet another embodiment, a method to increase a supply cooling fluid temperature of a cascade chiller system close coupled to air handlers is provided. The method includes monitoring positions of control valves on coils of air handlers close coupled connected to the cascade chiller system and increasing a supply cooling fluid temperature of the cascade chiller system as a function of an opening of at least one of the control valves.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

FIGS. 1 through 4 illustrate an example combination hybrid chiller and air handler system for data center use according to this disclosure;

FIGS. 5 through 8 illustrate additional views of the system of FIGS. 1 through 4 according to this disclosure;

FIG. 9 shows a dual chiller system with the chillers piped in series to form a cascade chiller system according to this disclosure;

FIG. 10 shows a schematic diagram of a combined fluid cooler and condenser assembly according to this disclosure;

FIG. 11 illustrates an example oven brazed aluminum micro-channel fluid cooling coil according to this disclosure;

FIG. 12 illustrates an example micro channel condenser coil slab according to this disclosure;

FIG. 13 shows a conventional fluid cooling coil;

FIG. 14 shows a conventional air-cooled condenser coil;

FIGS. 15 through 18 show simplified schematics of typical circuiting through the fin block;

FIG. 19 shows a schematic flow diagram of an example dual circuit cascade air cooled chiller with fluid economizers and combined fluid coolers and air-cooled condenser assemblies, according to this disclosure;

FIG. 20 illustrates an example flow diagram of the application of a dual circuit cascaded air-cooled chiller supplying cooling fluid to a close coupled air handling unit and several other supplemental loads, according to this disclosure;

FIG. 21 discloses an air side cascade system according to this disclosure;

FIG. 22 illustrates an example of a computing device for use in a data center environment according to this disclosure;

FIG. 23 shows an example flow chart of a method to control capacity of two chillers in part load conditions according to this disclosure; and

FIG. 24 shows an example flow chart of a method to increase a supply cooling fluid temperature of a cascade chiller system close coupled to air handlers according to this disclosure.

### DETAILED DESCRIPTION

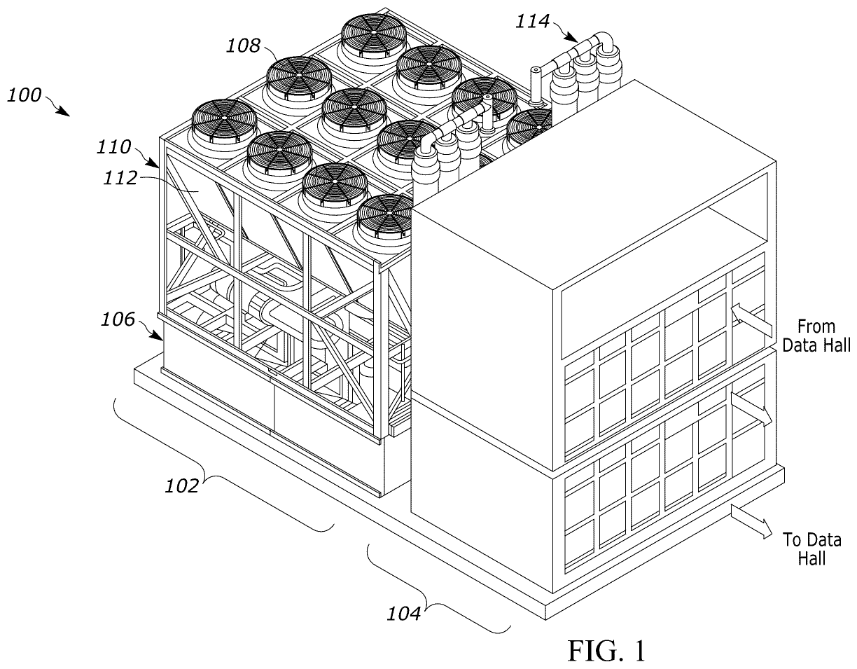

FIGS. 1 through 22, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

For simplicity and clarity, some features and components are not explicitly shown in every figure, including those illustrated in connection with other figures. It will be understood that all features illustrated in the figures may be employed in any of the embodiments described. Omission of a feature or component from a particular figure is for purposes of simplicity and clarity and is not meant to imply that the feature or component cannot be employed in the embodiments described in connection with that figure. It will be understood that embodiments of this disclosure may include anyone, more than one, or all of the features described here. Also, embodiments of this disclosure may additionally or alternatively include other features not listed here.

As discussed above, data center technology is currently in transition from air cooling techniques to liquid cooling techniques. The transition is occurring at an indeterminant rate, thus creating risk and requiring flexibility. Currently, operating temperatures are widely different among competing liquid cooling options. Also, increasing ambient temperatures are demanding increased operating range for cooling. Moreover, space is usually a premium resource in data center design. This requires careful consideration for chiller deployment, which requires spacing for airflow. In addition, principles of modularity for speed of deployment and economization at all operating conditions is important to take into consideration.

To address these and other issues, embodiments of the present disclosure provide a combination hybrid chiller and air handler. The disclosed embodiments include hybrid technology that supports both air cooling and fluid cooling simultaneously. Specifically, the air handler is water chiller based, modular, and supports a transitional migration from air to liquid cooling. The mix can be adjusted in real-time from 100% air cooling to 100% fluid cooling, and any ratio in between. In some embodiments, the condenser (refrigerant) and economizer (fluid) are interlaced. In other embodiments, the condenser and economizer are stacked. The disclosed refrigeration system is designed for higher temperatures and specifically supports the extended range required to handle both air-side and water-side cooling.

The disclosed embodiments provide multiple advantageous benefits over conventional chiller and air handler solutions. For example, the disclosed embodiments can include an air cooled chiller that does not require an evaporative water loop for heat rejection. In addition, the disclosed embodiments are scalable for many geographic locations. The disclosed embodiments provide high ambient operation without derate and provide simultaneous support of liquid and air cooling. The disclosed embodiments provide a very reliable design with screw compressors, lower peak energy, and lower annualized power usage effectiveness (PUE), all within a compact form factor with a high net capacity. The disclosed embodiments feature a simple scalable design with the possibility of side-by-side unit placement, and separation of the refrigeration and supply/return section, with support for roof and limited side yard applications.

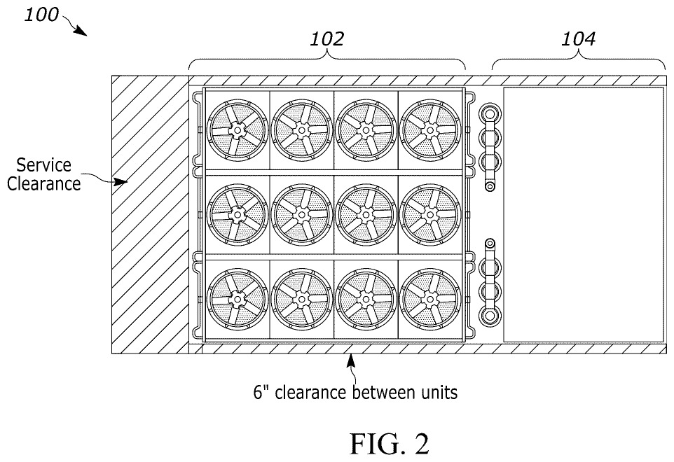

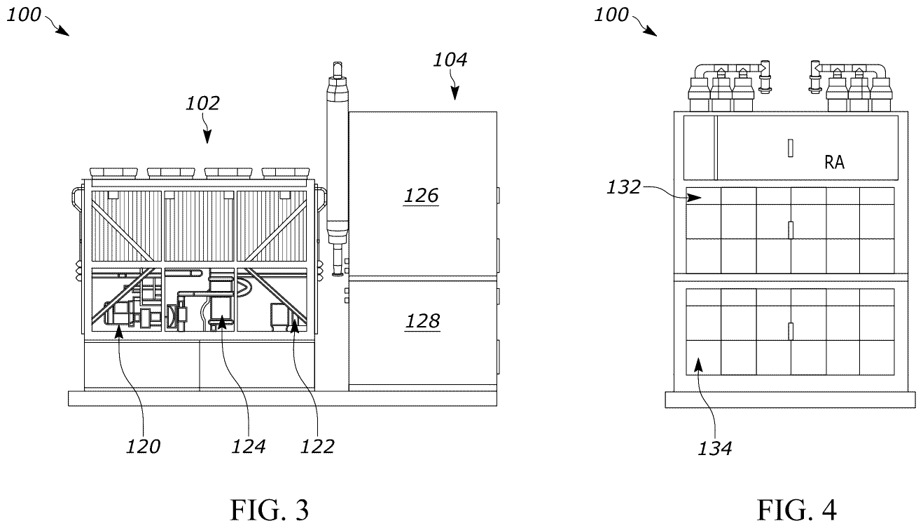

FIGS. 1 through 4 illustrate an example combination hybrid chiller and air handler system 100 for data center use according to this disclosure. In particular, FIG. 1 shows a perspective view of the system 100, FIG. 2 shows a top view of the system 100 with service clearance requirements indicated, FIG. 3 shows a side elevation view of the system 100, and FIG. 4 shows a front elevation view of the system 100. The embodiment of the system 100 shown in FIGS. 1 through 4 is for illustration only. Other embodiments of the system 100 could be used without departing from the scope of this disclosure.

As shown in FIGS. 1 through 4, the system 100 includes a chiller 102 that is disposed proximate to an air handler 104. The chiller 102 and the air handler 104 are close coupled, meaning that the chiller 102 and the air handler 104 are in close proximity to each other. In some embodiments, the chiller 102 and the air handler 104 are positioned such that an open space of twenty-four inches or less exists between the chiller 102 and the air handler 104, although the spacing can be as high as forty-eight inches or more to improve serviceability. Multiple instances of the chiller 102 and the air handler 104 can be arranged side-by-side for additional air handling and cooling capabilities. Each instance of the chiller 102 and the air handler 104 can be placed very close to a neighboring instance. For example, there can be an open space as small as six inches between adjacent chillers 102 and air handlers 104, such as shown in FIG. 2.

The chiller 102 is a high efficiency air cooler chiller with dual rotary screw compressors, multiple free cooling economizer coils, and a pump package. In some embodiments, the chiller 102 uses environmentally friendly, extended range 1234ze refrigerants, which significantly reduces energy consumption compared to other refrigerants. In some embodiments, the chiller 102 can be mounted on a platform 106, which can include one or more seismic curbs. The seismic curbs can be open at one end to allow air circulation and can be shipped in a broken down configuration for field erection. Multiple fans 108 are disposed on a top surface of the chiller 102. For maintenance and service, all service access for the chiller 102 and the air handler 104 can be from the back side 110 of the chiller 102. In some embodiments, a service corridor can be provided between the seismic curbs, starting at the back side 110 and extending toward the air handler 104.

FIG. 3 shows an example placement of the dual rotary screw compressors 120 and the pump package 122. In some embodiments, the pump package 122 includes dual circulation pumps with an expansion tank. The chiller 102 also includes one or more heat exchangers 124, which can be stainless steel brazed plate heat exchangers.

In some embodiments, the screw compressors 120 can feature a variable compression ratio with a dual side valve mechanism. In some embodiments, the screw compressors 120 can feature variable frequency drive (VFD) capacity control, which means near-zero in-rush current to the motor and electronic components, a rapid response to cooling load changes, and precise control of the chilled liquid temperature. Other features of the screw compressors 120 can include an advanced screw rotor profile, a low oil carry-over separator, and a dedicated oil circuit to cool and lubricate bearings and rotors, thus providing quiet operation and low vibration.

The chiller 102 features a cascade design and integrates automatic free cooling without the issues associated with introducing outside air directly into the facility. To enable free cooling, the chiller 102 includes a stacked system of multiple ambient air heat rejection coils 112 disposed below the fans 108. One coil is for the refrigeration system condenser coil and contains refrigerant. The second coil is a free cooling coil and is stacked in the direction of airflow with respect to the first coil. The free cooling coil directly cools the process cooling fluid of the chiller 102 using ambient air, without the need for compressor operation, when the ambient air temperature is low enough to deliver the required process cooling fluid temperature. The stacked system of coils 112 in the chiller 102 allows for better space utilization with an air cooler chiller that has a free cooling circuit.

As shown in FIGS. 1 and 4, the air handler 104 can be a stacked outdoor air handling unit with an upper level 126 and a lower level 128. In some embodiments, data hall air supply is provided at one level, while the return side is received at another level. The air handler 104 includes various fans and cooling coils. The air handler 104 can also include an upper section filter bank 132 and a lower section filter bank 134. In some embodiments, final filter service can be performed from inside the data hall building (not shown).

The system 100 also includes one or more cold water storage tanks 114, which can be disposed between the chiller 102 and the air handler 104. The tanks 114 can store cold water, which can provide a short duration (e.g., about two minutes) of thermal ride through during power transitions.

The system 100 is designed for higher temperatures and specifically supports the extended range required to handle both air side and water side cooling. In some embodiments, the system 100 is capable of operation exceeding 120° F. By using extended range refrigerants, the system 100 supports the operating ranges required for air and liquid cooling. In some embodiments, the system 100 supports single side access and side-by-side deployment with CFD driven air flow enhancements to support uniform airflow.

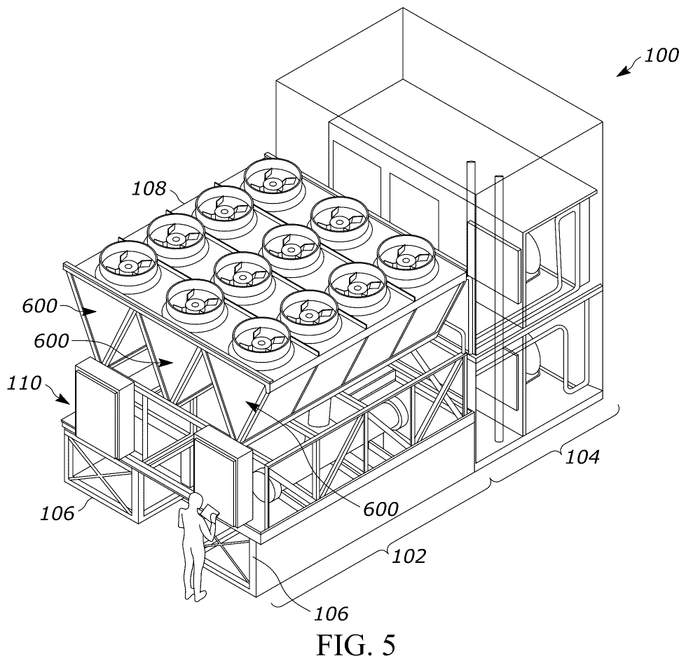

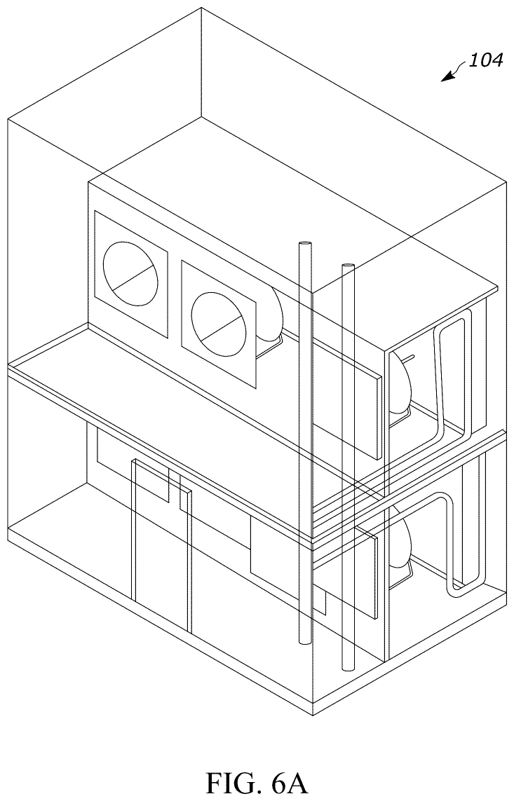

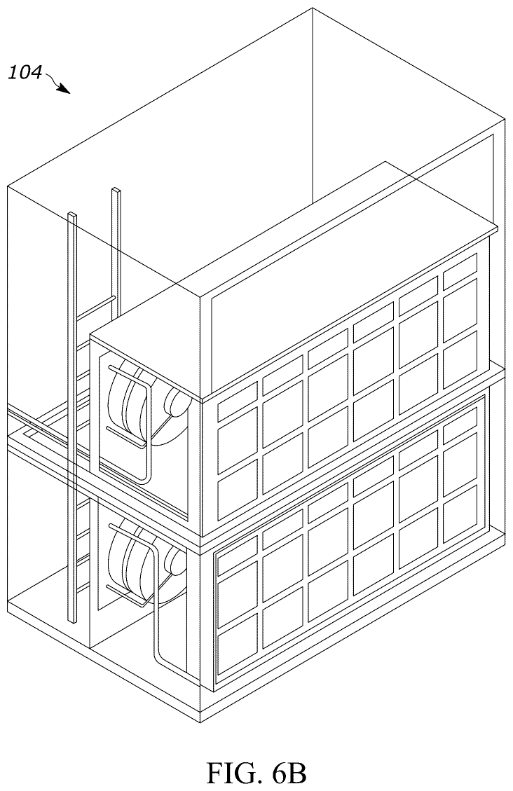

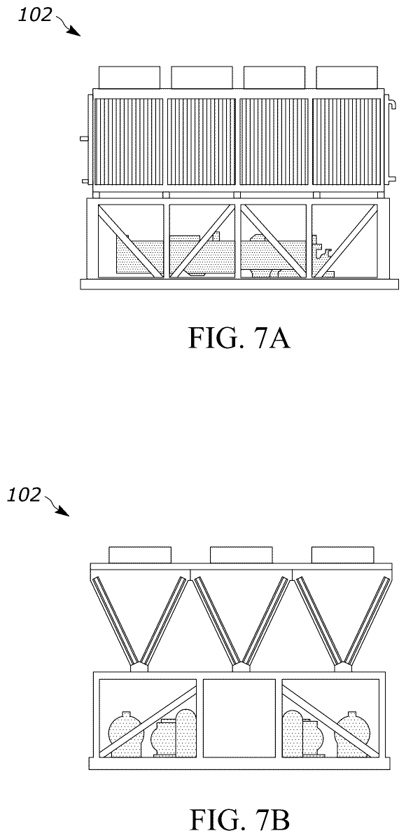

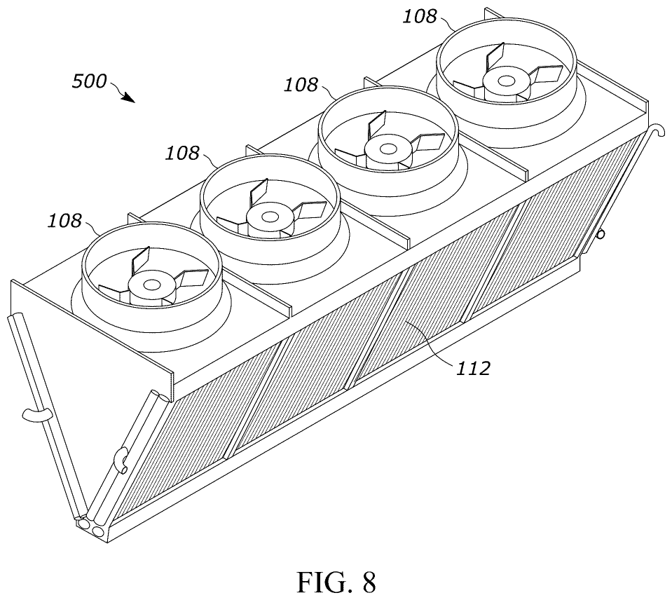

FIGS. 5 through 8 illustrate additional views of the system 100 according to this disclosure. In particular, FIG. 5 shows a perspective view of the system 100 from the back side 110, FIGS. 6A and 6B show views of the air handler 104 from the chiller side (FIG. 6A) and from the data hall side (FIG. 6B), FIGS. 7A and 7B show partial side and end views of the chiller 102, and FIG. 8 shows a perspective view of a condenser module 500 that is part of the chiller 102.

As shown in FIG. 5, the system 100 includes three condenser modules 500 arranged side-by-side at the top of the chiller 102. In some embodiments, the condenser modules 500 feature refrigerant condenser circuits interlaced with glycol/water economizer circuits. As shown in FIG. 8, each condenser module 500 includes multiple fans 108 disposed above the coils 112. In some embodiments, the coils 112 are arranged as 50 degree V-bank coil pairs. A baffled center support isolates sections of the coils 112 into separate air chambers. This prevents air from “back wheeling” through a failed fan 108, thus minimizing the impact of a fan loss. In some embodiments, the design of the chiller 102 provides for air entry on the refrigerant connection side only. This design feature can result in uneven airflow across the face of the fans 108. The speed of the fans 108 can be individually adjusted to compensate for this.

In some embodiments, the system 100 can include a liquid cooled motor in the fan wall and the condenser modules 500 to support extended ambient temperatures not viable for air cooled motors and provide enhanced MTBF on the fans 108 and increased motor efficiency.

In some embodiments, various control methods can be used to promote efficient operation of the system 100. For example, some control methods can be performed for control of air flow, and some control methods can be performed for control of water temperature.

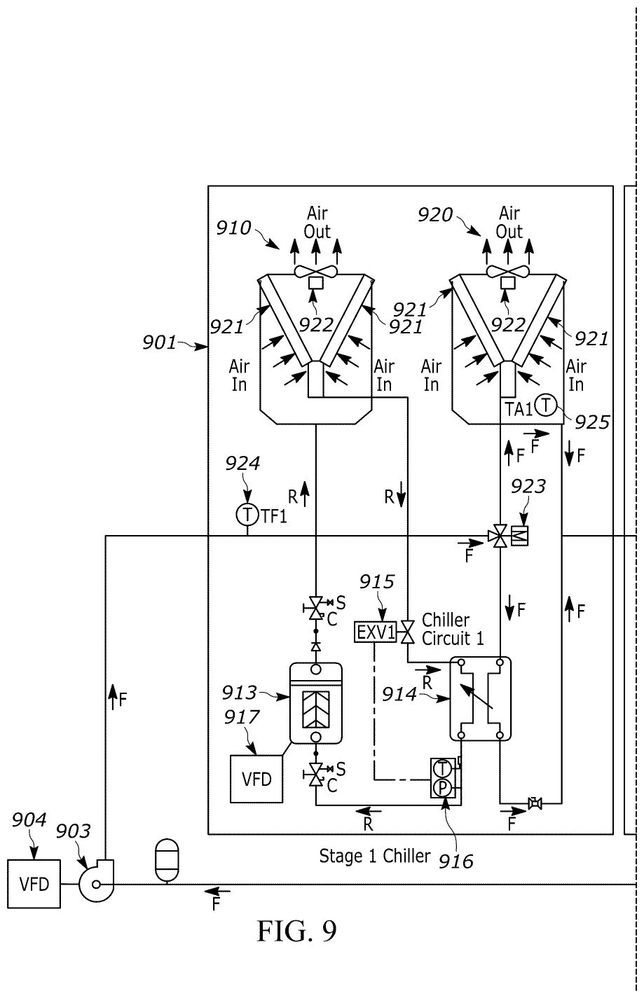

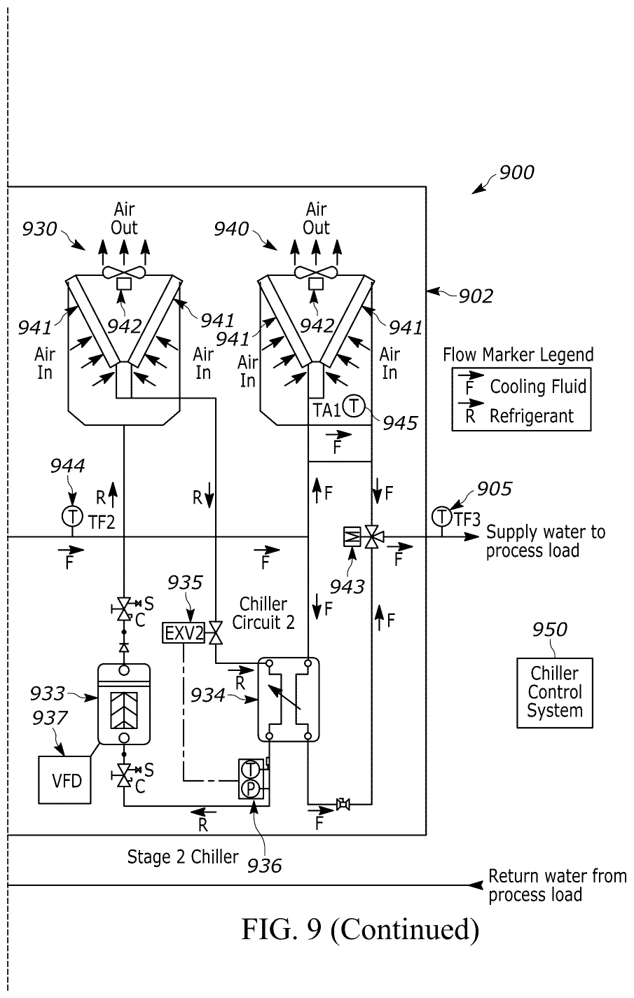

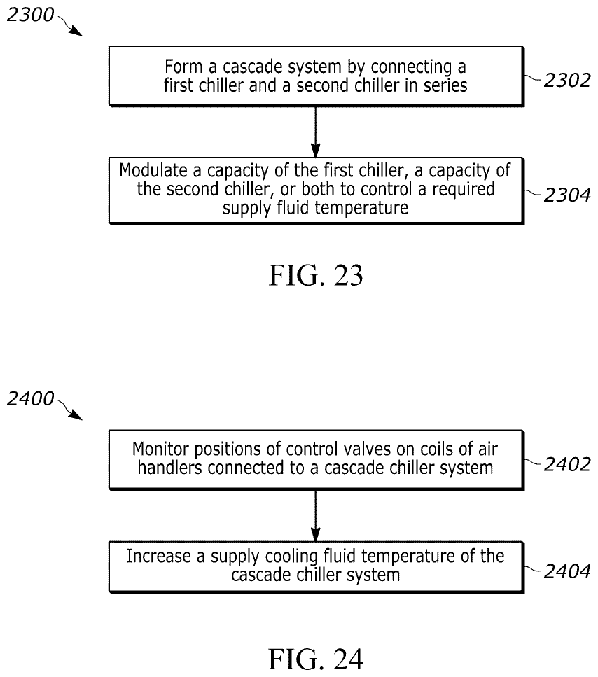

FIG. 9 shows a dual chiller system 900 with the chillers piped in series to form a cascade chiller system according to this disclosure. FIG. 23 shows an example flow chart of a method 2300 to control capacity of two chillers in part load conditions according to this disclosure. For example, the first stage chiller 901 and the second stage chiller 902 may be connected in series to form the cascade chiller system 900 (step 2302). The first stage chiller 901 receives the warm return water first and provides about half of the cooling by reducing the return fluid temperature by about half of the temperature difference required by the chiller system 900. The second chiller 902 receives the partially cooled fluid and cools it to the supply cooling fluid temperature required by the load. Each chiller has a refrigeration circuit to modulate a capacity of the chiller to control a required supply fluid temperature (step 2304). The basic parts are shown in FIG. 9. For the first stage chiller 901, they are the refrigeration compressor 913 with capacity modulation means 917, the air-cooled condenser 910, the refrigerant-to-water heat exchanger 914, expansion valve 915 with associated refrigerant temperature, and pressure sensor package 916 for suction superheat control. For the second chiller 902, they are the refrigeration compressor 933 with capacity modulation means 937, the air-cooled condenser 930, the refrigerant-to-water heat exchanger 934, expansion valve 935 with associated refrigerant temperature and pressure sensor package 936 for suction superheat control. The capacity modulation means for the compressors is preferably a variable speed drive, for example, that varies a rotational speed of the compressor by varying a position of an inlet valve to expose a swept area on an inlet side of the compressor. Each chiller has its own independent refrigerant piping that connects the components together. The refrigeration load and operating conditions are different between the first stage chiller 901 and the second chiller 902 so the selected components and refrigerant line sizes for each chiller can be different.

The benefit of a cascade system is that it can provide increased refrigeration efficiency because at least half of the compressor load can be delivered at higher efficiency because the required lift is reduced on the lead compressor. When a cascade system is employed with a free cooling heat exchanger, free cooling can start at higher ambient temperatures than it could in a non-cascaded system. Cascade systems use a lower water flow rate because they can cool loads with higher temperature differentials. This reduces piping costs and pumping energy.

For example, with a data hall employing air handlers with cooling coils to directly cool the data hall IT equipment, the air temperature supplied to the data hall could be around 75° F. When the air passes through the computer equipment in the data hall, it picks up as much as 30° F. in temperature rise, so the air returning to the air handling unit could be 105° F. And after it passes through the fans in the air handler, the air entering the coils could be as high as 107° F. A typical cooling coil design would need 65° F. water to supply the required air temperature of 75° F. and return the water to the chillers at 97° F. The efficiency of an air-cooled chiller goes up when its evaporating temperature rises. To deliver 65° F. of supply water to the coils, the chiller would typically require an evaporating temperature of around 60° F.

The compressor power input of an air cooler chiller is dependent on the difference between the ambient air temperature entering the chiller's condenser coils and the 60° F. evaporating temperature required to get 75° F. air into the data hall. The efficiency of the air-cooled chiller is directly related to that difference because it defines the pressure differential that the compressor must operate against to deliver the necessary cooling capacity. The higher that differential, the more work the compressor must do, which results in more power input into the compressor and lower cooling efficiency. This differential is often called “lift.” If two chillers are piped in parallel to deliver the required capacity, that lift is not changed, so the efficiency is not affected.

The two chillers 901 and 902 are piped in series to form a water side cascade chiller system. With each chiller taking half of the load, only the second stage compressor 933 has the same high lift, and that low efficiency is only applied to half of the load. The first stage compressor 913 only has to take the cooling water from 97° F. to 81° F., and the last compressor 933 can take it from 81° F. to 65° F. The first stage compressor 913 can operate at an evaporating temperature of 76° F. At 105° F. ambient, the lift is around 29° F. for the first stage compressor 913 and around 45° F. for the second stage compressor 933 in the cascade. Under these conditions, the first stage compressor may consume only about 65% of the power of the second compressor. Compared to a one-compressor system or a two-compressor system piped in parallel, the cascade system 900 requires only about 83% of the compressor power.

Because data halls and other process loads require cooling no matter what the ambient temperature is, economization (often called free cooling) is commonly provided. In office buildings, air side economization is often used, which requires outside air to be introduced directly into the building for cooling when ambient air temperatures allow. Air side economization is seldom used in data halls because of the added filtration necessary to keep pollutants out of the data hall and the expense of adding humidification during the winter months. On systems that use air cooled chillers, it is common to use air cooled fluid coolers to provide free cooling when the ambient temperature is low enough to drop the cooling fluid to a low enough temperature to cool the data hall. FIG. 9 shows that the cascaded chillers 901 and 902 are each provided with air cooled fluid coolers 920 and 940, respectively. The first stage chiller is provided with a three-way water valve 923 to divert the cooling fluid away from the refrigerant to fluid heat exchanger 914 to the air-cooled fluid cooler 920. When this is done the refrigerant compressor 913 is shut down and the fans 922 on the air-cooled fluid cooler 920 are turned on to provide cooling airflow over the fluid cooling coils 921. The second stage chiller 902 is also provided with an air-cooled fluid cooler 940 with cooling coils 941 and fans 942 and a three-way valve 943 to provide the same functionality.

On the first stage chiller 901, the three-way valve 923 is shown in the “diverting position” such that the cooling fluid is diverted from the inlet of the refrigerant to cooling fluid heat exchanger 914 to the inlet of the air-cooled fluid cooler 920 to enable free cooling. The outlets of the refrigerant to cooling fluid heat exchanger 914 and the air-cooled fluid cooler 920 are joined together to allow the cooing fluid to pass into the second stage chiller 902. On the second stage chiller 902, the three-way valve 943 is shown in the “mixing position” such that the water from the outlet of the refrigerant to cooling fluid heat exchanger normally flows through the valve to the outlet conduit of the second stage chiller 902. When the three-way valve 943 is switched, the outlet of the air-cooled fluid cooler 940 is connected to the outlet conduit and the outlet of the refrigerant to cooling fluid heat exchanger is blocked, forcing all of the cooling fluid through the air-cooled fluid cooler. Regardless of position, both valves 923 and 943 perform the same function, which is to direct the cooling fluid through either the air-cooled fluid cooler or the refrigerant to fluid cooling heat exchanger so the chiller control system 950 can pick the most economical path depending on the ambient entering the fluid cooler and the water temperature required from the cooling stage. Normally the chiller designer would pick either the “diverting position” or the “mixing position” for both valves depending on the design requirements of the chillers. FIG. 9 shows them in different positions for illustration purposes only.

On a system without cascaded chiller circuits, the free cooling will not start to operate until the ambient temperature is low enough that the free cooling coils can supply the water temperature required for the load. In this example, the supply water temperature would be at around 65° F. That would require the ambient temperature to drop below around 55° F. to do free cooling to operate without the compressors running. At higher ambient temperatures, the compressors would have to run to provide full cooling to the load.

On a cascade system, the free cooling can start at higher ambient temperatures. Using the example, the first stage chiller 901 can go into free cooling when the ambient temperature is low enough to deliver around 81° F. fluid temperature, which would be around 71° F. Thus, a cascade system with a fluid cooling economizer would deliver half of its required cooling without the compressor 913 in the lead chiller 901 at 71° F. As the ambient temperature falls further, the free cooling coils 921 in the lead chiller 901 will continue to reduce the fluid temperature leaving the free cooling coils, which will have the effect of reducing the load and power input of the second compressor 933. When the ambient temperature drops below around 60° F., the first stage fluid cooler 920 will have increased its capacity by around 45%, allowing the second stage compressor 933 to reduce its capacity to 55% of its design capacity. The fluid cooler on the second chiller 902 may be able to deliver the 65° F. water required by the load and the ambient temperature of 60° F., and the compressor in the second chiller can be shut off. Thus, the cascade system will provide 50% free cooling, starting at 71° F. and an increasing percentage of free cooling as the temperature drops to 60° F., at which point the free coolers 920 and 940 can provide 100% of the data processing heat load.

An ambient air temperature sensor 925 is provided on the first stage chiller 901, and an ambient air temperature sensor 945 is provided on the second stage chiller 902. These sensors are in the entering air stream of their chiller's fluid cooler to measure the ambient air temperature available for free cooling. A return fluid temperature sensor 924 is provided on the first stage chiller 901 and a return fluid temperature sensor 944 is provided on the second stage chiller 902. The return fluid temperature sensor 944 on the second stage chiller 902 also senses the leaving water temperature of the first stage chiller 901. A last stage supply fluid temperature sensor 905 is supplied to sense the fluid output temperature of the last chiller stage 902. These temperature sensors are used by the chiller control system 950 to control the temperature output of each and operating mode of each chiller stage to minimize the power consumption of the cascade chiller system 900 as described above. A pumping system 903 employed with a VFD 904 is employed to supply cooling fluid flow through the cascade chiller system 900 and applied load.

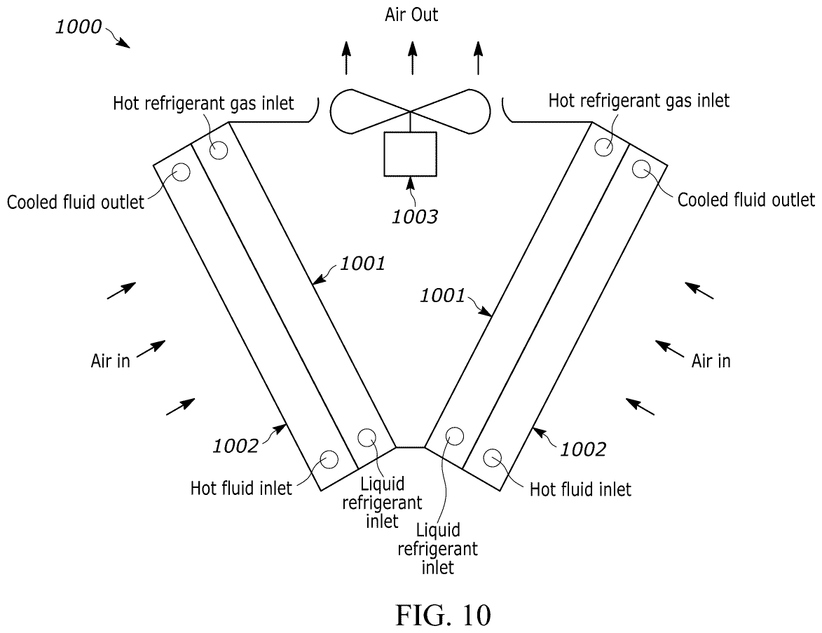

FIG. 9 show separate fluid coolers 920 and 940 and air-cooled condensers 910 and 930. Both fluid coolers and air-cooled condensers require fans and heat transfer coils and an enclosure to direct ambient airflow through the heat transfer coils and through the fans. These enclosures can be quite large and require a large footprint to accommodate both. Some embodiments use a combined fluid cooler and condenser assembly that is combined into a single enclosure with a common set of fans, as shown in FIG. 10.

FIG. 10 shows a schematic diagram of a combined fluid cooler and condenser assembly 1000 according to this disclosure. FIG. 24 shows an example flow chart of a method 2400 to increase a supply cooling fluid temperature of a cascade chiller system close coupled to air handlers according to this disclosure FIG. 8 shows the embodiment of FIG. 10 in a physical sense, showing the fans 108 that make up the fan system 1003 and the free cooling coils 112 which are shown as free cooling coils 1002 in FIG. 10, while the condenser coils 1001 are behind the free cooling coils 112 not visible in this view. The condenser coils 1001 and the fluid cooling coils 1002 are arranged in series so that cooling air passes in series from one to the next. This significantly reduces the cost and required footprint area. In this embodiment the free cooling coils 1002 are shown in ahead of the condenser coils 1001 in direction of airflow. Since they are not intended to operate simultaneously, the positions of the free cooling coils 1002 and the condenser coils 1001 are monitored (step 2402) could be reversed in the direction of the airflow with no effect on the efficiency of the free cooling operation of the system, such as by increasing the supply cooling fluid temperature (step 2404).

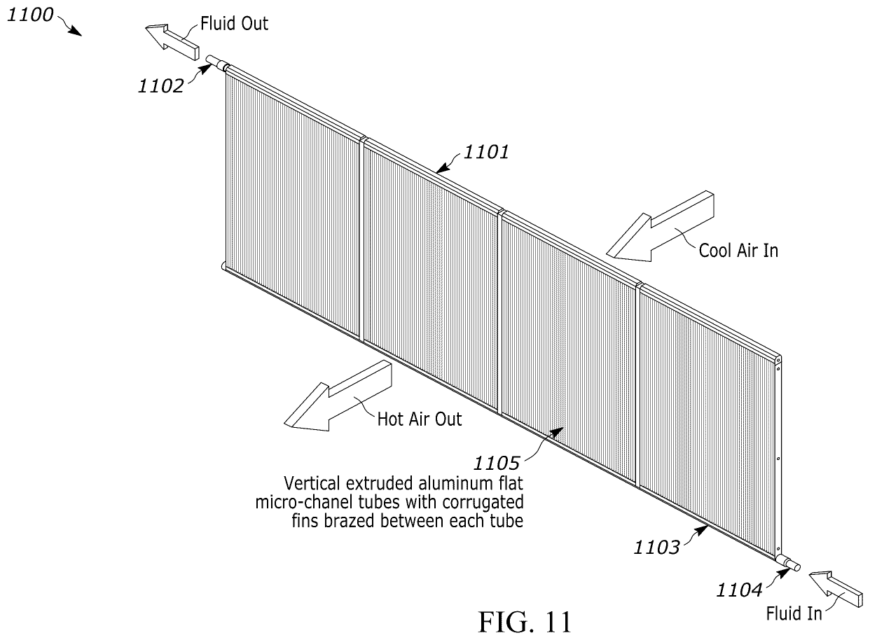

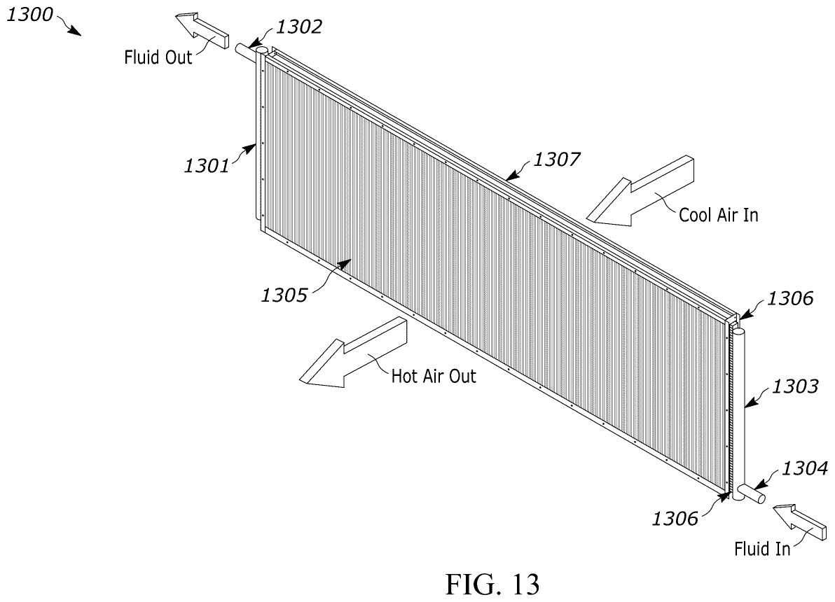

FIG. 11 illustrates an example oven brazed aluminum micro-channel fluid cooling coil 1100 according to this disclosure. This heat exchanger uses vertical flat extruded aluminum micro-channel tubes 1105 brazed into a horizontal fluid distributor 1103 and receiver 1101, respectively on the bottom and top of the heat exchanger. A fluid inlet 1104 is low and the cooling fluid travels through the horizontal fluid distributor 1103 and up through the micro channel tubes 1105. The cooling fluid is collected in the receiver 1101 where it is directed to a cooler outlet 1102. This configuration prevents air entrapment in the heat exchanger. Corrugated fins are brazed into the spaces left between the micro channel tubes 1105 to enhance the capacity of the heat exchanger. This arrangement has a lot more primary heat exchanger surface and is less reliant on the finned secondary surface area than a conventional fin tube cooling coil, such as shown in FIG. 13. This type of heat exchanger has been proven to be cost effective and more compact, with less airside pressure loss than comparable finned tube cooling coils of equal cooling capacity and similar face area.

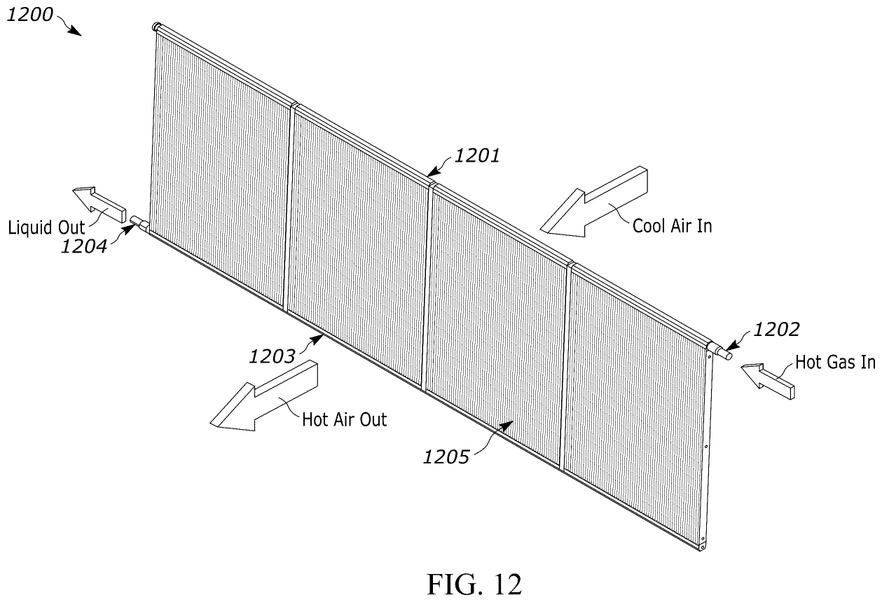

FIG. 12 illustrates an example micro channel condenser coil slab 1200 according to this disclosure. As shown in FIG. 12, the coil slab 1200 can be of identical size and shape as the fluid cooling coil 1100, but the hot refrigerant gas inlet 1202 along with the horizontal distributer 1201 is on the top of the coil. The refrigerant liquid outlet 1204 along with the horizontal receiver 1203 are on the bottom of the coil. The refrigerant travels through the micro channel tubes 1205 where it is condensed from a gas to a liquid. This arrangement promotes gravity drainage of the liquid refrigerant condensate.

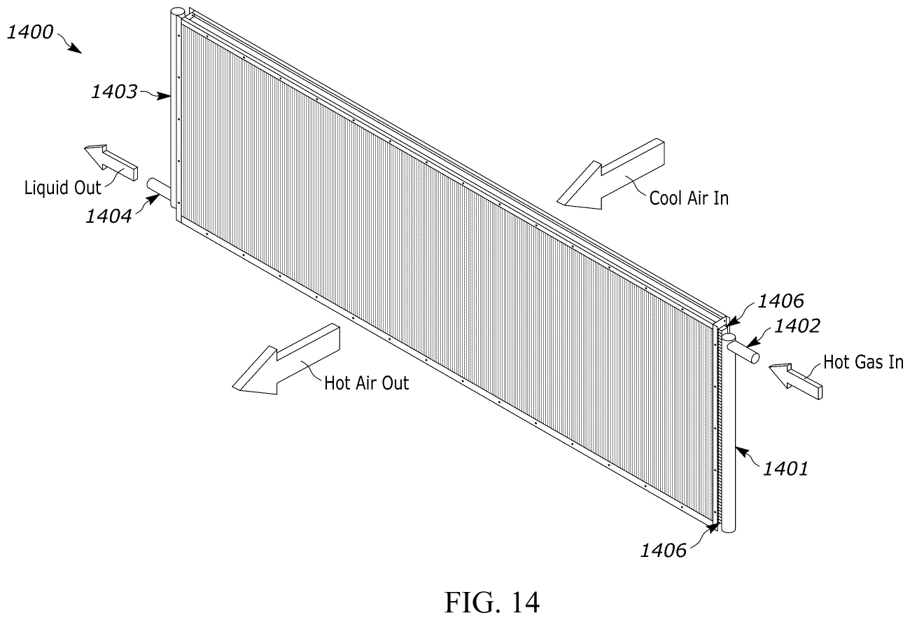

In some embodiments, conventional finned tube coils can be used to make a combined fluid cooler and condenser assembly 1000. FIG. 13 is an outline drawing of a conventional fluid cooling coil 1300 and FIG. 14 shows an outline drawing of a conventional air-cooled condenser coil 1400. These coils can be of the same general size and configuration as the micro-channel heat transfer coils used in the embodiments described earlier. The differences are mainly in the manner of construction and the materials used. The conventional finned tube cooling coils 1300 and 1400 as shown are configured to be interchangeable with the micro-channel coils in the combined fluid cooler and condenser assembly 1000 shown in FIG. 8 and FIG. 10.

As shown in FIG. 13, the finned tube cooling coil 1300 uses a plurality of round tubes 1306 mechanically expanded into a fin block made up of a plurality of heat transfer fins 1305 die formed on a mechanical fin press. A sheet metal casing 1307 is mounted around the fin block to protect the coil and mount the coil. The cooling fluid is distributed to the horizontal cooling tubes 1306 through a vertical inlet header 1303 with inlet nozzle 1304 and collected through a vertical outlet header 1301 with outlet nozzle 1302.

As shown in FIG. 14, the condenser coil 1400 includes a vertical inlet header 1401, a hot gas inlet connection 1402, a vertical outlet header 1403, a liquid refrigerant outlet connection 1404, and round tubes 1406. The condenser coil 1400 can have the same casing dimensions as the fluid cooling coil 1300 when mounted in the same housing to make the combined fluid cooler and condenser assembly 1000. The hot gas inlet connection 1402 as shown and the liquid refrigerant outlet connection 1404 would be in different locations and sizes than used by the fluid cooling coil 1300. Other coils parameters, such as fin count, tubing rows and circuiting could vary between the condenser coil 1400 and the fluid cooling coil 1300 to deal with the differences in required heat transfer rate and physical differences between the refrigerant gas and the cooling fluid. The flow paths are configured by connecting the tubes on the ends of the coils with return bends so they form a serpentine path through the fin block.

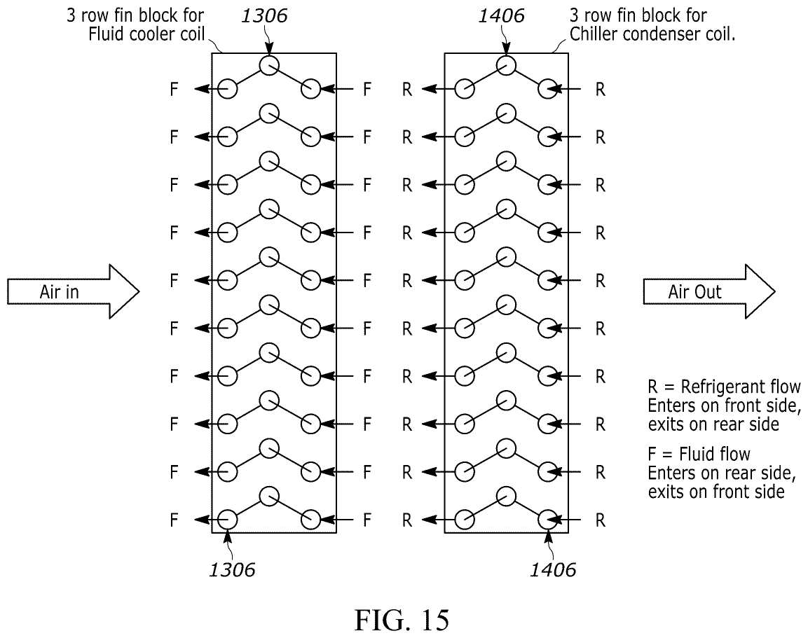

FIGS. 15 through 18 show simplified schematics of typical circuiting through the fin block. When using conventional finned tube coils to make a combined fluid cooler and condenser assembly 1000, it is often advantageous to combine the fluid cooling coil 1300 and the condenser coil 1400 into one coil block and design the tube circuiting to be interlaced. The example fin tube coils shown in FIGS. 13 and 14 are both three-row coils with the inlet and outlet connections on opposite sides.

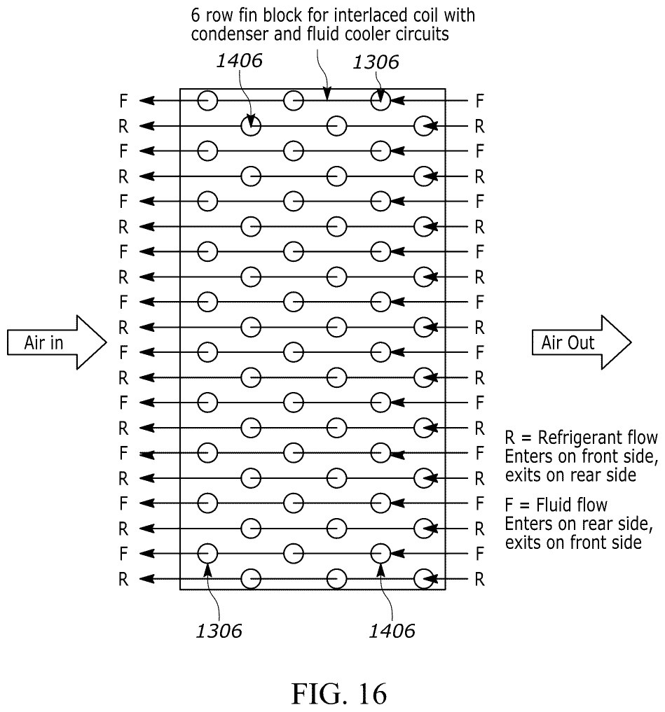

FIG. 15 shows the tube circuiting of a section ten tubes high for each of these coils mounted as it would be in the combined fluid cooler and condenser assembly 1000 shown in FIG. 10. This can represent a typical ten tube high section on one side of the V coil in FIG. 10. The fluid cooling coil 1300 circuiting is shown first in the airflow stream and the condenser coil 1400 circuiting second just as in FIG. 10. Because these coils do not operate at the same time, it is possible to combine them into one six-row fin block and interlace the circuits, as shown in FIG. 16. Instead of circuiting the coils in the row spit fashion, with separate casings as they are in FIG. 15, the individual circuits are spread out over the entire six rows of the coil which only needs one casing. Both the condenser and the fluid cooler keep the same number of tubes and the same number of circuits and passes as they had before, so the primary surface area of each heat exchanger is the same.

In the direction of airflow, there is still the same number of total rows so the air side pressure loss will be virtually the same. The advantage of this circuiting is that the active function will have more secondary fin area to transfer heat to the air stream. This provides better thermal performance for both functions than they would have if separate coils were used with no penalty in cost or air pressure loss.

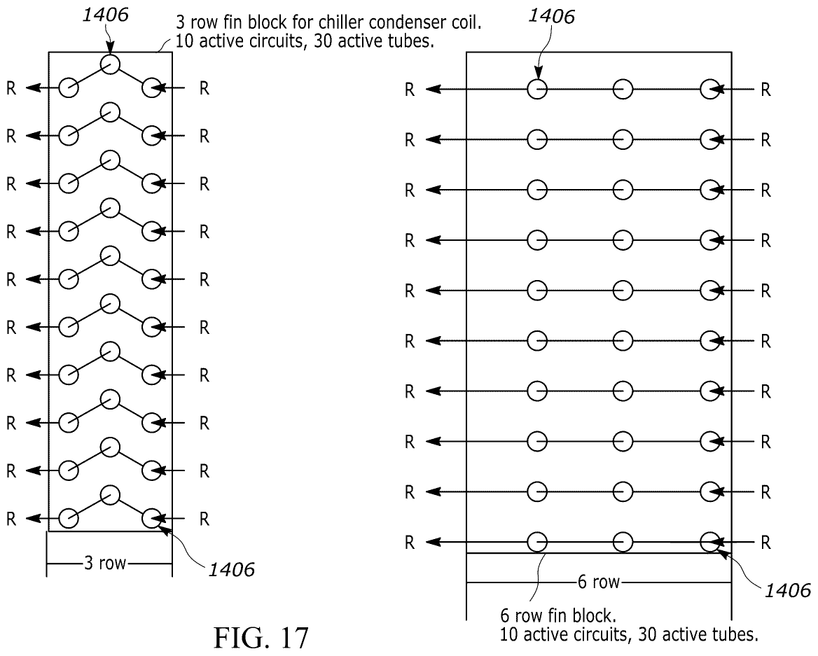

This is demonstrated in FIG. 17. The original condenser coil circuits in the three-row coil are shown next to the condenser coil circuits in the interlaced coil. The tubes and circuits for the fluid cooler are not shown on the interlaced coil, as they are not active and are not participating in any heat transfer to or from the airstream. By not showing the inactive tubes in FIG. 17, the figure graphically demonstrates the increased fin area available to the active condenser surface with the interlaced design. As can be seen, there is two times the fin area available to each active air-cooled condenser tube in the interlaced design than there is when separate coils are used.

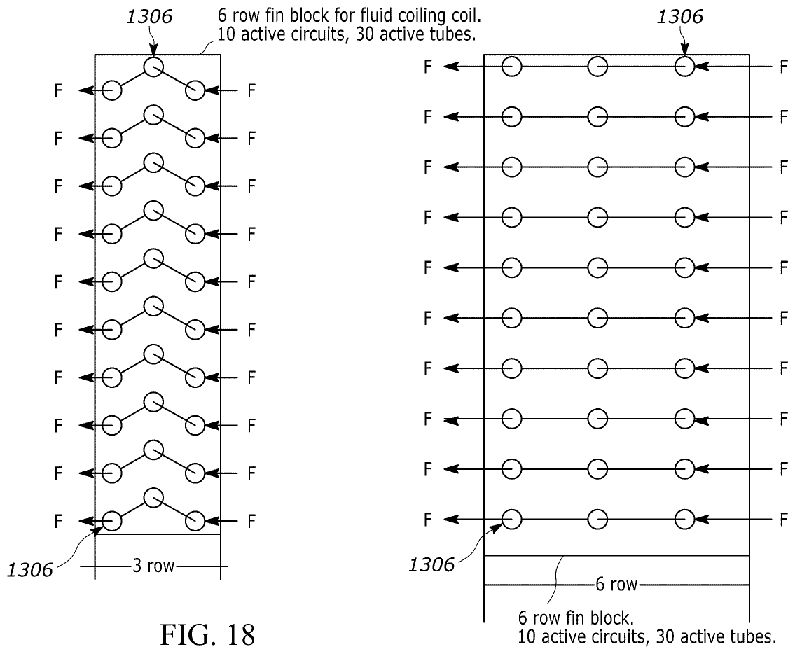

FIG. 18 makes the same comparison for the fluid cooling circuits and shows the same benefit for fluid cooling. This increases the heat transfer capacity of the interlaced coil comes at no increase in cost and no increased air pressure loss when compared to the fin tube coil solution using separate air-cooled condenser and fluid cooler coils.

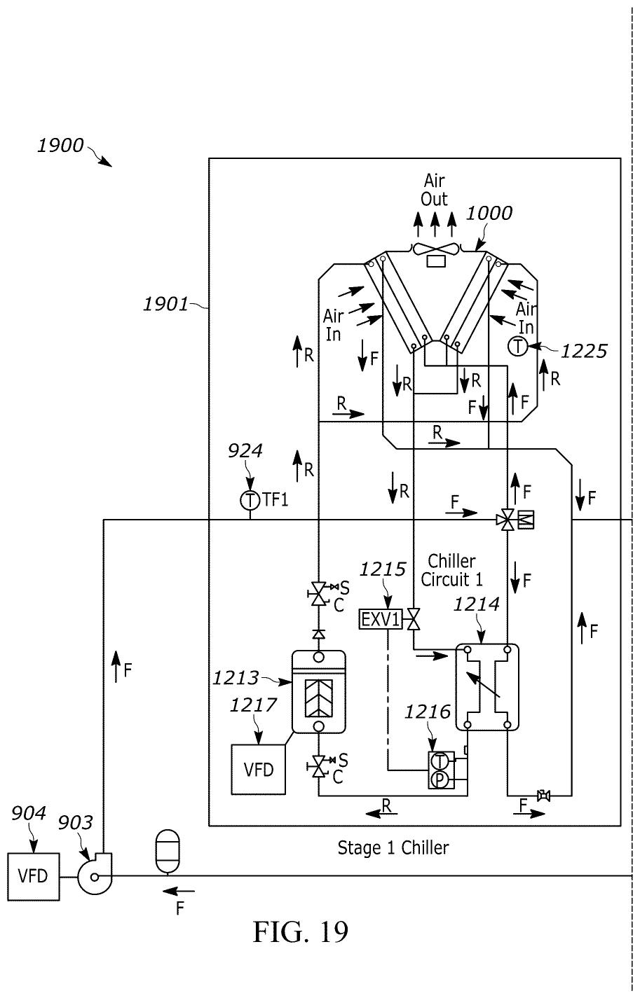

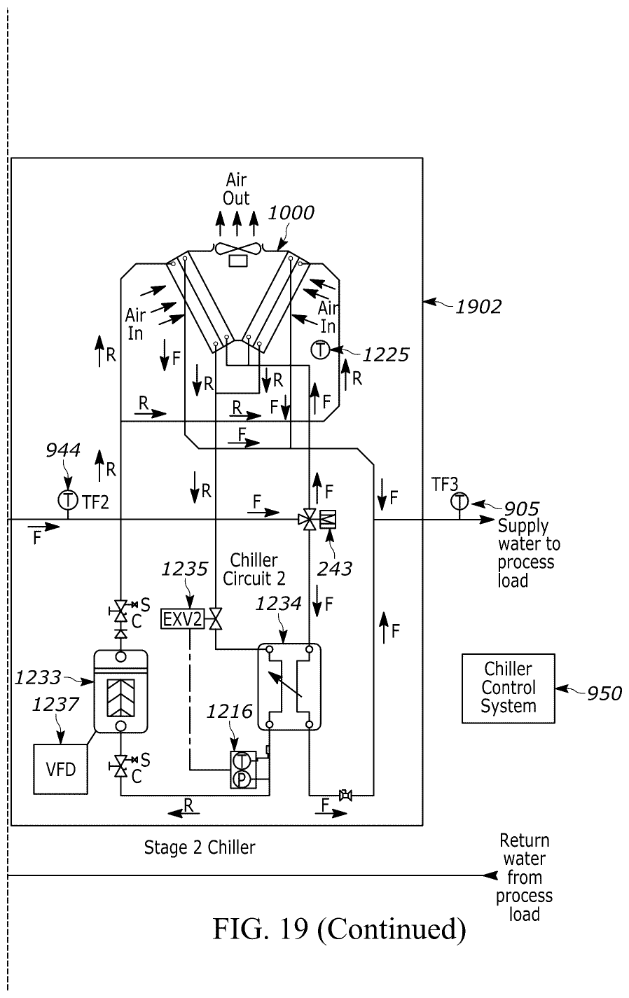

FIG. 19 shows a schematic flow diagram of an example dual circuit cascade air cooled chiller system 1900 with fluid economizers and combined fluid coolers and air-cooled condenser assemblies, according to this disclosure. It is the functional equivalent of the dual circuit cascaded air-cooled chiller system 900 with fluid cooler economizers disclosed in FIG. 9. It uses a separate combined fluid cooler and condenser 1000 for both the lead chiller 1901 and second stage chiller 1902 in place of the separate air-cooled condenser assemblies and fluid cooler assemblies shown in FIG. 9. The combined fluid cooler and condenser assemblies 1000 can use micro-channel coils as shown in FIGS. 11 and 12 for the fluid cooling coils 1002 and condenser coils 1001. It could also use conventional fin tube coils as shown in FIGS. 13 and 14 for the fluid cooling coils 1002 and the condenser coils 1001. Lastly, conventional fin tube fluid cooling coils 1300 and condenser coils 1400 could be combined together into a single interlaced with a single coil casing with isolated circuits for the condenser function and for the fluid cooler function. It is understood that some embodiments use a V shaped configuration with a set of condenser and fluid cooler coils on each side of the fans, but there are many other physical configurations that could be used to design a combined fluid cooler and condenser assembly.

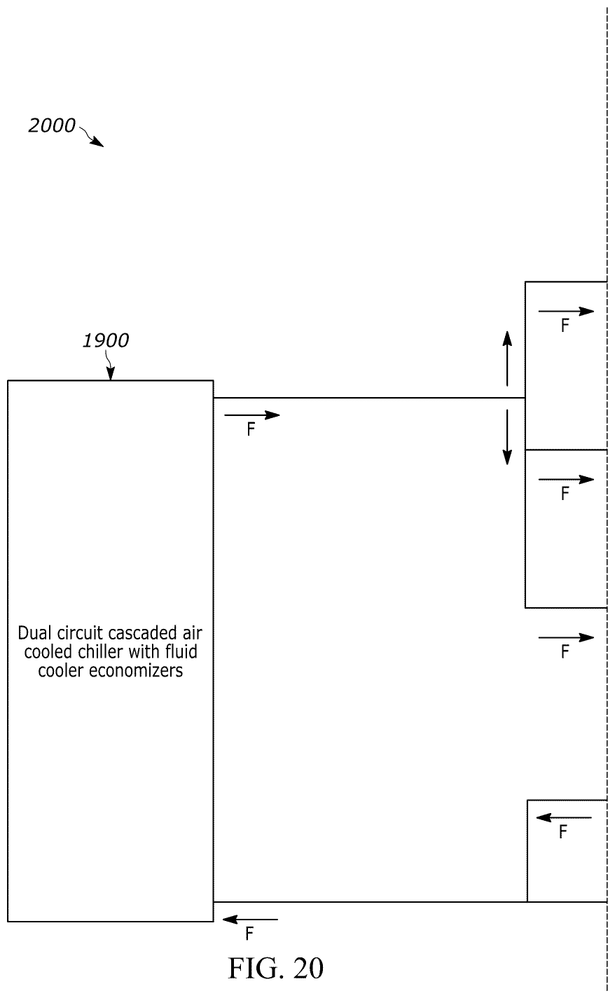

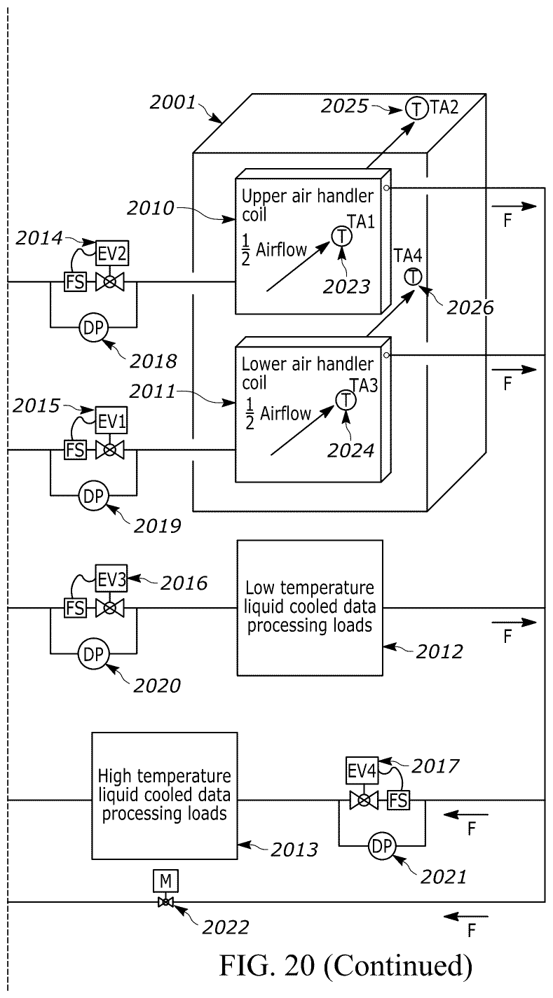

FIG. 20 illustrates an example flow diagram of a system 2000 applying the dual circuit cascaded air-cooled chiller 1900 supplying cooling fluid to a close coupled air handling unit 2001 and several other supplemental loads, according to this disclosure. Here, the air handling unit 2001 can represent (or be represented by) the air handler 104 of FIG. 1. Each load has one or more flow control valves to adjust the flow through the individual loads. The close coupled air handling unit 2001 is the main load of the chiller 1900 and is shown with two coils. The upper coil 2010 has a flow control valve t to control its flow of cooling fluid, and a pressure differential sensor 2018 is used to measure the fluid pressure drop across flow control valve 2014. Similarly, the lower coil 2011 of the air handling unit 2001 has a flow control valve 2015 and a pressure differential sensor 2019. The air handling unit 2001 provides cooling air to the data processing equipment inside of the data hall. To do so, cold fluid is used by cooling coils to cool hot return air drawn from data processing equipment and return it to the data hall. In this figure, the upper coil 2010 in the air handling unit 2001 is stacked directly over the top of the lower coil 2011. The flow across each coil is roughly one half of the total air handling unit 2001. This arrangement is commonly called face splitting the air flow across the coils and is common in most large air handling units.

Other equipment inside of the data hall could use direct fluid cooling from the chiller system. These can be divided into two groups. The first is low temperature loads 2012 that would use the same cooling fluid temperature supplied to the cooling coils of the air handling unit. For example, some modern high-capacity computing systems can be located in the IT racks of a data hall and have provisions for direct liquid cooling ports built into their hardware. These high-capacity computing systems sometimes require air cooling as well as liquid cooling. Additionally, other computing equipment may be deployed in the IT racks that only require the cool air supplied by the air handling unit. The low temperature loads 2012 would be provided with their own flow control valve 2016 and its pressure differential sensor 2020.

A second group of loads that could use direct fluid cooling from the chiller 1900 are loads that can use higher cooling fluid supply temperatures than the cooling coils of the air handling unit 2001. There are high-capacity computing systems that are designed for direct immersion in a dielectric fluid bath. Because the dielectric fluid is substantially more efficient in removing heat from the components of the high-capacity computing systems, the dielectric fluid bath temperature can be much higher that the air temperature traditionally used to cool those components. The dielectric fluid bath temperature could be as high as 120° F. to 150° F. and still provide sufficient cooling to keep the components of the high-capacity cooling systems within their design operating parameters. The cooling coils of the air handling unit will normally require the supply temperature of the cooling fluid leaving the chiller 1900 to be around 65° F. and will return that fluid at around 97° F. The cooling fluid temperature leaving the cooling coils 2010 and 2011 of the air handling unit 2001 is low enough to cool the dielectric fluid bath in the direct immersion systems.

While the supply cooling fluid could be used for dielectric fluid bath cooling, there are several advantages to using the warmer cooling fluid leaving the cooling coils. One advantage is that it reduces the flow rate required for the chiller 1900. Reducing the flow rate reduces the required pump size and the size of the interconnecting piping in the chiller and to and from the low temperature loads. Another advantage is that it increases the return temperature of the cooling fluid, which in turn increases the capacity of the free cooling systems and allows for more free cooing hour of operation.

For example, if the load from the high temperature liquid cooler data processing loads 2013 were 20 percent of the low temperature loads from the air handling unit 2001 cooling coils 2010 and 2011, the return water temperature would increase by 6.4° F. With the cascade design of chiller system 1900, the fluid temperature leaving the lead chiller 1901 would increase from around 81° F. to around 84.2° F. This would increase the ambient air temperature at which the lead chiller 1901 switches off the compressor and diverts the cooling fluid into the free cooling coils 1002 from around 71° F. to around 74.2° F. If one examines typical weather data for any given area in North America that might use one of these systems, one will find a significant number of hours in a year's time that fall in this band. In Los Angeles, there are 726 hours in the band, which amounts to 8.2% of the year. In central Virginia, there are 710 hours in this band, or 8.1% of the year.

Each load type and coil in the air handling unit has a pressure independent flow control valve. These valves can supply a specific cooling flow amount to the load they serve based on the command given to the valve by the chiller control system 950. This type of valve has a flow measuring device included in the valve assembly that allows them to be pressure independent. They can produce the commanded flow over a wide variety of inlet pressures, which the valve will internally compensate for. Without this feature, the individual branches that require cooling fluid flow would need to be mechanically balanced. That usually involves placing a manual balancing valve in each flow branch to try to equalize the pressure loss through each branch with its full flow. This is a time consuming, iterative process, which is difficult to accomplish in the field. It also imposes additional pressure losses across the system, thereby driving up the required pumping energy.

These valves typically require a minimum pressure differential to produce the commanded flow. This is usually accomplished by placing a pressure sensor in the cooling fluid supply line before it branches out to the individual loads. The main cooling fluid circulation pumping system 903 is equipped with a means to vary flow and pressure, usually a VFD 904. The pump is modulated to maintain a set pressure at the aforementioned pressure sensor. The set pressure is usually determined by running the system at design flow and measuring the pressure differential across each valve. The pressure is increased until every valve has enough pressure to operate properly. That pressure then becomes the set point pressure that controls the fan. As the valves in the system 2000 modulate down because of lower load, the set point pressure remains the same and there is more than enough pressure for all of the valves. Because these types of systems seldom deliver full or maximum load, the pumps are usually producing more pressure than necessary, thus wasting pumping energy. The system 2000 shown in FIG. 20 demonstrates an improved method to control the pumps to minimize pumping energy.

All the flow control valves shown in FIG. 20 have pressure differential sensors that measure the pressure loss across the control valve. The valves 2016 on the low temperature supplemental loads and the valves on the cooling coils 2010 and 2011 vary their flow according to the demand from the device on their branch determined by the chiller control system 950. The chiller control system 950 will monitor the pressure difference across each of these valves and increase the pump speed using the VFD 904 until all the pressure differential sensors 2018, 2019, and 2020 on the flow control valves read at or above the minimum differential required by the control valve for proper operation.

The chiller control system 950 continues to monitor the pressure differential of all these valves and uses the valve with the lowest pressure differential to control the pump speed. The control valve 2017 on the high temperature liquid cooling load 2013 that draws water from the return water stream has a pressure differential sensor 2021 to measure its pressure loss. A motorized balancing valve 2022 is placed in the main return water line that bypasses the branch with the high temperature liquid cooling load 2013. The chiller control system 950 modulates the control valve 2017 to meet the demands of the high temperature liquid cooled data processing loads. As the valve 2017 modulates, the chiller control system 950 monitors the pressure differential sensor 2021. The chiller control system 950 modulates the motorized balancing valve 2022 until the pressure differential across the flow control valve 2017 is at the minimum pressure required for proper operation of the valve 2017. If there are other valves supplying cooling fluid to high temperature loads from the return water line, the valve with the lowest pressure differential can control the modulating balance valve 2022.

This method requires no manual adjustment and set up. It is flexible for changing loads. It always keeps the restriction in the return fluid bypass line at the minimum possible for control of the high temperature loads. The pump speed is always at the minimum required for control of the system flow through the low temperature and cooling coil loads. If there are no loads drawing cooling fluid from the return water, the pump speed control method does not change and the motorized balancing valve 2022 on the return cooling fluid line is not required.

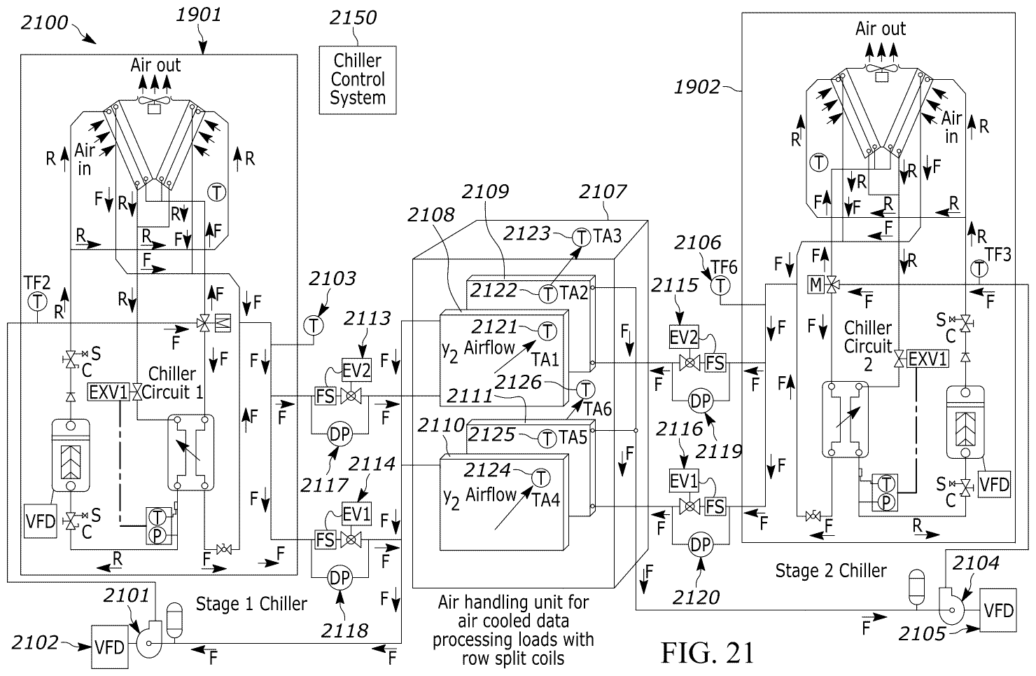

FIG. 21 discloses an air side cascade system 2100, which includes the chiller 1901 and the chiller 1902, according to this disclosure. As shown in FIG. 21, the chiller 1901 is close coupled to cooling coils 2108 and 2110. The coil 2108 sits on top of the coil 2110 in a face split arrangement. A flow control valve 2113 controls the cooling fluid flow through the top coil 2108. A flow control valve 2114 controls the cooling fluid flow through the bottom coil 2110. The top cooling coil 2108 takes the air entering the air handling unit 2107 and cools it from air temperature TA1 to the intermediate air temperature TA2 as shown in FIG. 21. The bottom cooling coil 2110 takes the air entering the air handling unit 2107 and cools it from air temperature TA4 to the intermediate air temperature TA5. Under normal operation, TA1 and TA4 are expected to be the same. TA2 and TA5 are expected to be controlled to the same intermediate air temperature by the chiller control system 2150.

A temperature sensor 2121 is provided to measure air temperature TA1 and supply that information to the chiller control system 2150. Similarly, temperature sensor 2124 is provided to measure air temperature TA4. Temperature sensor 2122 is provided to measure air temperature TA2 to use as a control point for the chiller control system 2150. Similarly, temperature sensor 2125 is provided to measure air temperature TA5 to use as a control point for the chiller control system 2150. Chiller 1901 and cooling coils 2108 and 2110 form the first stage of the air side cascade. A separate pumping system 2101 with flow modulation means 2102 provides the cooling fluid flows for the first stage of the air side cascade, and fluid temperature sensor 2103 is provided to control the supply cooling fluid temperature that feeds coils 2108 and 2110.

The chiller 1902 is close coupled to cooling coils 2109 and 2111. Coil 2109 sits on top of coil 2111 in a face split arrangement. Flow control valve 2115 controls the cooling fluid flow through the top coil 2109. Flow control valve 2116 controls the cooling fluid flow through the bottom coil 2111. The top cooling coil 2109 takes the air leaving the coil 2108 and cools it from the intermediate air temperature TA2 to the leaving air temperature TA3 as shown in FIG. 21. Cooling coils 2108 and 2109 are arranged in a row split configuration. The bottom cooling coil 2111 takes the air leaving coil 2110 and cools it from the intermediate air temperature TA5 to the leaving air temperature TA6. Under normal operation TA3 and TA6 are expected to be controlled to the same leaving air temperature by the chiller control system 2150. Temperature sensor 2123 is provided to measure air temperature TA3 to use as a control point for the chiller control system 2150. Similarly, temperature sensor 2126 is provided to measure air temperature TA6 to use as a control point for the chiller control system 2150. Chiller 1902 and cooling coils 2109 and 2111 form the second stage of the air side cascade. A separate pumping system 2104 with flow modulation means 2105 provides the cooling fluid flow for the second stage of the air side cascade, and fluid temperature sensor 2106 is provided to control the supply cooling fluid temperature that feeds coils 2109 and 2111.

FIG. 21 shows the top set of coils face split from the bottom set of coils. This would be typical on larger air handling units just as it is shown on the system disclosed in FIG. 20 with the water side cascade chillers. In both cases, half of the airflow goes through the top coils and half goes through the bottom coils. If small air handling units are used, the coils would not be face split, and only the bottom coils would be used. The distinction between the two systems disclosed is that the chillers 1901 and 1902 are piped in series in FIG. 20 to form a water side cascaded chiller, the coils are not row split, and only one pumping system is required. On the air side cascade system disclosed in FIG. 21, the same chillers 1901 and 1902 are independent with their own pumping systems. The chiller 1901 is connected to the first set of coils 2108 and 2110 in the row split. The air side cascade is formed by connecting the second stage chiller 1902 and pumping system 2104 to the downstream set of coils 2109 and 2111 in the row split. The air side cascade system can be shown to give the same benefits as the water side cascade system.

Using the same air side conditions used in the example for the water side cascaded chillers, the air temperature TA3 and TA6 leaving the air handling unit and entering the data hall would be 75° F. The IT equipment would heat the air up to 105° F., and the air handling unit 2107 would draw it into the circulating fans (not shown) where it would pick up 2° F. as it passed through the fans. The air temperature (TA1 and TA4) entering the coils 2108 and 2110 on the entering air side of the row split would be 107° F. The coils 2108 and 2110 would be designed to pick up half of the sensible load, which would load the first stage chiller at 50% of the total.

The air temperature (TA2 and TA5) leaving coils 2108 and 2110 would be 91° F. and enter the coils on the entering air side of the row split coils 2109 and 2111 and leave at an air temperature (TA3 and TA6) of 75° where it would enter the data hall. The coils on the leaving air side of the row split coils 2109 and 2111 would pick up the rest of the sensible load and load the second stage chiller at 50% of total. The supply cooling fluid temperature delivered by the first stage chiller 1901 would be 81° F., which would require a compressor evaporating temperature of 76° F. The supply cooling fluid temperature of the second stage chillers 1902 would be 65° F., which would require a compressor suction temperature of 60° F. The fluid cooling coils on the first stage chiller would be turned on at an ambient air temperature of 71° F. and the system would go into 100% free cooling at 60° F. at full load operating conditions. These operating conditions are the same for both the first stage chiller system 1901 and the second stage chiller system 1902 of the water side cascade system 2000 and provide the same efficiencies.

The air side cascade system 2100 of FIG. 21 is functionally equivalent to the preferred water side cascade embodiment but may be more expensive, due to more complex piping and piping requirements, and may be less flexible in application as it would be more difficult to accommodate supplemental loads and multiple air handlers.

Data halls are designed for maximum resiliency and employ multiple redundancy strategies to minimize the need to shut down the IT equipment. Data halls are filled with highly concentrated heat sources which cannot operate without cooling equipment to remove the heat from the hall. In order to accommodate cooling equipment failures and to allow cooling equipment to be shut off for maintenance, a redundant cooling unit is typically provided for the data hall. It is not unusual to provide 5 cooling units for a data hall and select the capacity of the cooling using so that 4 units can handle the maximum hall cooling load. Under this strategy, all 5 units run continuously at 80% of their maximum capacity. If a cooling unit fails or is taken offline, the remaining 4 units can increase their output to meet the cooling load in the data hall. For example, a data hall with a cooling load of 2,500 kW would require a net cooling capacity of 625 kW from each of 4 units to satisfy the cooling load. When all 5 units are running, they would need to deliver 500 kW of cooling capacity each to satisfy the cooling load. The cooling units would run at 80% of their design capacity under normal circumstances and rarely operate at 100%.

Data halls measure their load by the sum of the nominal power consumption ratings of all the installed equipment. It is unusual for all the installed equipment to reach the maximum power consumption at the same time. In a fully deployed data hall, it is unusual to see a load factor over 90%. The loads are usually reasonably constant, and good network operators can keep the load factors between 80% to 90%. Given these facts, the operation of the cooling equipment at 70% of its design cooling load is very representative of a fully deployed data hall, and the fully loaded condition is rare. The method of control should be designed to minimize power consumption at 70% load to minimize the power consumption of the hall.

Referring to the water side cascade system 2000 shown in FIG. 20, it is noted that most systems with chillers supplying cooling fluid to air handling units control the supply fluid temperature at a fixed temperature, and vary the cooling fluid flow through the coils of the air handling units to deliver a constant air temperature in part load conditions. In the examples given, the supply cooling fluid temperature was shown to be 65° F. The coils of the air handler would then be selected to deliver the required air temperature to the equipment in the data hall at 75° F. at the design flow rate of cooling fluid. This will be referred to as the traditional method of control in the succeeding paragraphs. There is some variation in these numbers, depending on the needs of the customer, so these example values are used for explanation of the controls.

With the traditional method of control, the controls for the air handling unit, which in this case could also be the chiller control system 950, can modulate the airflow through the coils 2010 and 2011 to match the airflow required by the computing devices in the data hall that the air handling unit serves. This establishes that load on the air handling unit coils and in a close coupled cooling system the load on the chillers. The controls for the air handling unit will modulate the flow control valves 2014 and 2015 to maintain a constant supply air temperature leaving the coils using air temperature sensors 2023 and 2024 mounted in the airstream leaving the cooling coils. The chiller control system 2150 will modulate the capacity of the chiller to provide the constant output temperature of 65°. This system has variable cooling fluid flow with constant cooling fluid supply temperature. The supply cooling fluid temperature holds constant during part load conditions, and the flow control valves 2014 and 2015 are controlled to restrict the flow to coils 2010 and 2011 to hold the supply air temperature (TA2 and TA4) delivered to the data hall using supply air temperature sensors 2025 and 2026. The pumping system 903 modulates the flow of the cooling fluid to match the flow required by the control valves 2014 and 2015.

The traditional method of control has efficiency improvements and reduced power draw at part load conditions. The efficiency will continue to improve as the ambient air temperature drops. Operation at part load also allows the free coiling systems of each chiller stage to engage at higher ambient temperatures, thus increasing the number of hours of free cooling operation for each stage. These compressor efficiency improvements and free cooling hour increases are ultimately limited by the strategy to keep the supply cooling fluid fixed at 65° F. That means that no matter the load, the compressor 933 evaporating temperature on the second stage chiller 1902 will be below 65° F. It also means that the ambient air temperature entering the free cooling coils will be below 65° F. to eliminate compressor operation.

When this water side cascade chiller system is close coupled to one or several air handling units as shown in FIG. 20, an improved control method can provide better part load results. Maintaining maximum flow through coils 2010 and 2011 of the air handling unit 2001 and varying the supply cooling fluid temperature leaving the chiller system 1900 allows the supply cooling fluid temperature to rise above 65° F. in part load conditions. This allows the compressor evaporating temperature on the second stage chiller 1902 to rise above 65 degrees, thus reducing the lift and increasing the second stage compressor efficiency. The change over ambient temperature when both free cooling systems are running can be above 65° F., thus increasing the number of free cooling hours of operation.

For example, chillers designed to deliver 625 kW of cooling capacity at 105° F. at design load with each stage of the water side cascaded chiller system 1900 delivering 312.5 KW of cooling capacity at 65° F. supply fluid temperature can deliver the following performance characteristics at the full load of 625 kW of cooling capacity:

The air handling unit 2001 delivers 75° F. supply air to the data hall, which returns to the air handling unit 2001 at 105° F., picking up 2° F. of fan heat and delivering it to the cooling coil at 107° F. The cooling fluid returned from the air handling unit coils has a temperature of 97° F.

At 105° F. ambient temperature, the first stage of the chiller system 1901 delivers 312.5 kW of cooling capacity with the compressor evaporating temperature of 76° F. and consumes 45.6 kW of compressor power. The second stage of chiller system 1901 delivers 312.5 kW of cooling capacity with the compressor evaporating temperature of 60° F. and consumes 64.4 kW of compressor power. The total compressor power for the chiller system 1901 is 110 kW to deliver 625 kW of cooling capacity at 105° F. for a cooling unit efficiency (COP) of 5.7.

At 85° F. ambient temperature, the first stage of the chiller system 1901 delivers 312.5 kW of cooling capacity with the compressor evaporating temperature of 76° F. and consumes 27.8 kW of compressor power. The second stage of chiller system 1901 delivers 312.5 kW of cooling capacity with the compressor evaporating temperature of 60° F. and consumes 43.0 kW of compressor power. The total compressor power for the chiller system 1901 is 110 kW to deliver 625 kW of cooling capacity at 85° F. for a cooling unit efficiency (COP) of 8.8. The free cooling for stage 1 engages and delivers 50% of the cooling capacity at 71° F. The free cooling for stage 2 engages at 60° F. and delivers 28% of the cooling capacity with the first stage delivering 72% at that temperature.

At 70% load, the chillers only need to deliver 437.5 kW of cooling capacity to the air handling unit 2001, which in turn can reduce its air flow by 30%. The supply air can be delivered to the data hall at 75° F., which returns it to the air handling unit coils at approximately the same air temperature of 107° F.

At 70% load with the traditional method of variable flow control of the cooling fluid to hold the supply air temperature constant at 75° F., the flow can be reduced to 65% of the flow required at 625 kW, which results in the cooling fluid returning from the air handling unit to the dual water side cascade chiller 1900 at 99.3° F. With a 70% load factor and a dual stage water side cascade chiller system splitting the load equally between both stages, as is done at full load, this does not produce the lowest chiller power consumption. The lowest compressor power consumption occurs when the high efficiency first stage is fully loaded to 312.5 kW of cooling capacity, and all the load reduction occurs in the lower efficiency second stage, which would be loaded to 125 kW of cooling capacity. The first stage of free cooling can be enabled when the ambient temperature is low enough to pick up 125 kW of the cooling load. When the first stage of free cooling is enabled, the second stage compressor picks up 312.5 kW of cooling capacity. This allows the first stage of free cooling to be enabled as soon as the second stage chiller has enough capacity to supply the balance of the load. The cascade chiller system can achieve the following performance when it uses the traditional variable flow method to control the supply temperature of the air handling unit.

At 105° F. ambient temperature, the first stage of the chiller system 1901 can deliver 312.5 kW of cooling capacity with the compressor evaporating temperature of 70° F. and consumes 52.6 kW of compressor power. The second stage of the chiller system 1901 can deliver 125 kW of cooling capacity with the compressor evaporating temperature of 63° F. and consumes 18.4 kW of compressor power. The total compressor power for the chiller system 1901 can be 71 kW to deliver 437.5 kW of cooling capacity at 105° F., for a compressor efficiency (COP) of 6.2.

At 85° F. ambient temperature, the first stage of the chiller system 1901 can deliver 312.5 k kW of cooling capacity with the compressor evaporating temperature of 70° F. and consumes 33.1 kW of compressor power. The second stage of chiller system 1901 can deliver 125 kW of cooling capacity with the compressor evaporating temperature of 63° F. and consumes 9.2 kW of compressor power. The total compressor power for the chiller system 1901 is 42.3 kW to deliver 437.5 kW of cooling capacity at 85° F., for a COP of 9.2.

The free cooling for stage 1 can engage and deliver 125 kW of the cooling capacity at 85.6° F. At that point, the second stage chiller can load up to deliver 312.5 kW of cooling capacity with the compressor evaporating temperature of 60° F. and a power input of 43.6 kW. As the temperature continues to fall, the free cooler for stage 1 continues to increase in capacity until the ambient temperature reaches 62° F., at which point the first stage free cooler delivers 78% of the cooling load, the compressor in the second stage chiller can be turned off, and the free cooler for stage 2 delivers the remaining 22% of the cooling load.

With the improved method of constant flow and variable temperature control of the cooling fluid to hold the supply air temperature constant at 75° F., the cooling fluid flow can be the same as the cooling fluid flow required at the design capacity of 625 kW. The chiller control system 2150 can increase the cooling fluid temperature supplied to the air handling unit coils 2023 and 2024 to 70.8° F., which allows them to deliver 75° F. cooling air at 70% flow and a data hall load 437.5 kW. The temperature of the cooling fluid returning to the first stage of cascaded chiller is 93.1° F. Using the same chiller loading scheme outlined for the traditional variable flow control method, the improved method of variable temperature control can result in the following performance improvements.

At 105° F. ambient temperature, the first stage of the chiller system 1901 can deliver 312.5 kW of cooling capacity with the compressor evaporating temperature of 72° F. and consumes 49.8 kW of compressor power. The second stage of chiller system 1901 can deliver 125 kW of cooling capacity with the compressor evaporating temperature of 68.8° F. and consumes 15.1 kW of compressor power. The total compressor power for the chiller system 1901 can be 65 kW to deliver 437.5 kW of cooling capacity at 105° F., for a COP of 6.8. This represents an 8.5% reduction in compressor power required at this condition, as compared to the traditional control method.

At 85° F. ambient temperature, the first stage of the chiller system 1901 can deliver 312.5 k kW of cooling capacity with the compressor evaporating temperature of 77.1° F. and consumes 31 kW of compressor power. The second stage of chiller system 1901 can deliver 125 kW of cooling capacity with the compressor evaporating temperature of 68.8° F. and consumes 8.2 kW of compressor power. The total compressor power for the chiller system 1901 can be 39.1 kW to deliver 437.5 kW of cooling capacity at 85° F., for a COP of 11.2, representing a 7.6% reduction in compressor power at this condition, as compared to the traditional control method.

The free cooling for stage 1 engages and delivers 125 kW of the cooling capacity at 83° F. At that point, the second stage chiller can load up to deliver 312.5 kW of cooling capacity with the compressor evaporating temperature of 66° F. and a compressor power input of 34.9 kW, representing a 20% reduction in compressor power at this condition. As the temperature continues to fall, the free cooler for stage 1 continues to increase in capacity until the ambient temperature reaches 67° F. and the chiller system can operate without compressors, an improvement of 5° F. At this point, the first stage free cooler supplies 78% of the cooling load, the compressor in the second stage chiller can be turned off, and the free cooler for stage 2 delivers the remaining 22% of the cooling load.

In one embodiment, two or more independent air-cooled chillers are piped in series to cool a process cooling fluid. Each independent air-cooled chiller contains a valve to direct the entering process cooling fluid to the chiller for mechanical cooling or to an air-cooled fluid cooler with the outlet of the chiller and the outlet of the air-cooled fluid cooler joined together before the fluid exits the chiller. In some examples, each chiller's air-cooled condenser heat transfer surface and fluid cooler heat transfer surface are combined in a single assembly sharing a fan system to force cooling air through the heat transfer surfaces. In some examples, each the system of the two or more independent air-cooled chillers piped in series is controlled to direct the process cooling fluid of each chiller stage away from the air-cooled chiller and to the free cooling coil by comparing the required process cooling fluid temperature at the outlet of that stage to the ambient air temperature available to the fluid cooler.

In another embodiment, two or more independent air-cooled chillers are piped to one or more air handling units. The coils of each air handling unit are split into the number of sections equal to the number of air-cooled chillers. Said coil sections are arranged in series with the air handling unit airflow and each coil section is piped to a different independent chiller. Each independent air-cooled chiller contains a valve to direct the entering process cooling fluid to the chiller for mechanical cooling or to an air-cooled fluid cooler for free cooling with the outlet of the chiller and the outlet of the air-cooled fluid cooler joined together before the fluid exits the chiller. In some examples, each chiller's air-cooled condenser coil and fluid cooler coil are combined in a single assembly sharing a fan system that directs the air from the fan system through the fluid cooling coil and the air-cooled condenser coil in series. In some examples, this system including two or more independent air-cooled chillers piped to one or more air handling units is controlled to direct the process cooling fluid of each chiller stage away from the air-cooled chiller and to the free cooling coil by comparing the required process cooling fluid temperature at the outlet of that stage to the ambient air temperature available to the fluid cooler.

In another embodiment, a method to control the part load capacity of two independent chillers arranged in series is provided to form a cascade system and each chiller having capacity modulation, that minimizes or reduces power consumption by maximizing or increasing the capacity of the first chiller in the cascade and modulating the capacity of the second chiller in the cascade to control the required supply fluid temperature.

In some examples, the method further includes to begin lowering the capacity of the first chiller in the cascade system when the modulating capacity of the second chiller in the cascade reaches its minimum and still lower cooling capacity is required to maintain the required supply cooling fluid temperature.

In some examples, the first chiller in the cascade system has an economizer and the cascade systems' cooling fluid is diverted into said airside economizer and the refrigeration compressor in the first chiller in the cascade is shut off when the combined capacity of the economizer capacity of the first chiller added to the refrigeration capacity of second chiller in the cascade system can meet the required capacity of said cascade chiller system. In one example, the economizer is an airside economizer.

In some examples, the second chiller in the cascade system has an economizer and the cascade systems' cooling fluid entering the second chiller is diverted into said airside economizer and the refrigeration compressor in the second chiller in the cascade system is shut down when the economizer capacity of second chiller in the cascade system added to the capacity of first chiller in the cascade chiller system can meet the required capacity of said cascade chiller system. In one example, the economizer is an airside economizer.

In some examples, the chillers are air-cooled.

In some examples, the cooling capacity of the refrigeration compressors in the chillers are modulated by varying their rotational speed.

In some examples, the cooling capacity of the compressors refrigeration compressors of are screw compressors and are modulated by varying the position of the inlet valve to expose swept area on the inlet side of the screw rotors.

In some examples, the chiller has multiple compressors, and the capacity of the chiller is modulated by switching compressors on and off.

In another embodiment, a method to raise the supply cooing fluid temperature of a cascade chiller system used with a close coupled air handlers in a data hall at partial load to reduce chiller power consumption by monitoring the positions of all of the control valves on all of the close coupled air handler coils connected to said chiller system and raising the chiller system's supply cooling fluid temperature as a function of the opening of the valve(s), for example, until at least until at least one valve is around 100% open.

Although FIGS. 1 through 21 illustrate examples of combination hybrid chiller and air handler systems and related details, various changes may be made to FIGS. 1 through 21. For example, various components in the disclosed systems may be combined, further subdivided, replicated, rearranged, or omitted and additional components may be added according to particular needs. In addition, while FIGS. 1 through 21 illustrate example combination hybrid chiller and air handler systems for use in data centers, the described functionality may be used in any other suitable device(s) or system(s).

Further, any of the above described embodiments and/or examples can be utilized independently or in combination with one or more other of the above described embodiments and/or examples. The above flowcharts illustrate example methods that can be implemented in accordance with the principles of the present disclosure and various changes could be made to the methods illustrated in the flowcharts herein. For example, while shown as a series of steps, various steps in each figure could overlap, occur in parallel, occur in a different order, or occur multiple times. In another example, steps may be omitted or replaced by other steps.

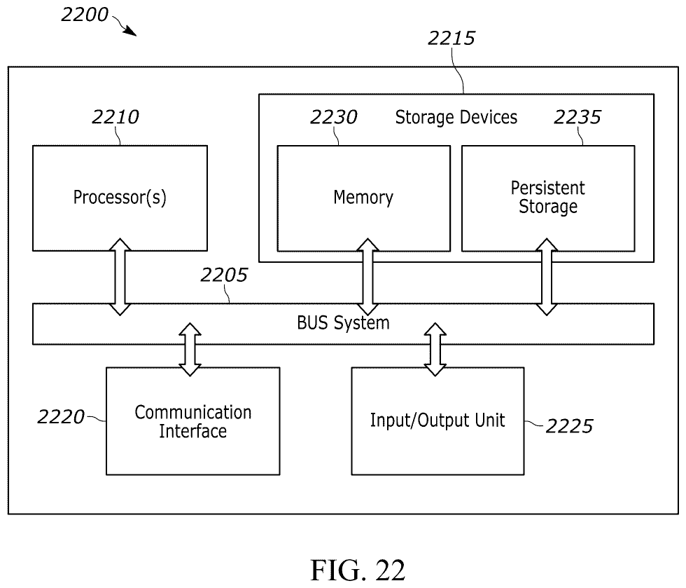

FIG. 22 illustrates an example of a computing device 2200 for use in a data center environment according to this disclosure. The computing device 2200 can be configured to control operations in various components in any of the systems disclosed above. For example, the computing device 2200 may control or monitor operations associated with the chiller 102, the air handler 104, the control systems associated with these, or any combination of these.

As shown in FIG. 22, the computing device 2200 includes a bus system 2205, which supports communication between processor(s) 2210, storage devices 2215, communication interface (or circuit) 2220, and input/output (I/O) unit 2225. The processor(s) 2210 executes instructions that may be loaded into a memory 2230. The processor(s) 2210 may include any suitable number(s) and type(s) of processors or other devices in any suitable arrangement. Example types of processor(s) 2210 include microprocessors, microcontrollers, digital signal processors, field programmable gate arrays, application specific integrated circuits, and discrete circuitry.

The memory 2230 and a persistent storage 2235 are examples of storage devices 2215, which represent any structure(s) capable of storing and facilitating retrieval of information (such as data, program code, and/or other suitable information on a temporary or permanent basis). The memory 2230 may represent a random access memory or any other suitable volatile or non-volatile storage device(s). The persistent storage 2235 may contain one or more components or devices supporting longer-term storage of data, such as a read-only memory, hard drive, Flash memory, or optical disc. For example, persistent storage 2235 may store one or more databases of data, standards data, results, data, client applications, etc.

The communication interface 2220 supports communications with other systems or devices. For example, the communication interface 2220 could include a network interface card or a wireless transceiver facilitating communications between data center components. The communication interface 2220 may support communications through any suitable physical or wireless communication link(s). The I/O unit 2225 allows for input and output of data. For example, the I/O unit 2225 may provide a connection for user input through a keyboard, mouse, keypad, touchscreen, or other suitable input devices. The I/O unit 2225 may also send output to a display, printer, or other suitable output devices.

Although FIG. 22 illustrates one example of a computing device 2200, various changes may be made to FIG. 22. For example, various components in FIG. 22 could be combined, further subdivided, or omitted and additional components could be added according to particular needs. As a particular example, while depicted as one system, the computing device 2200 may include multiple computing systems that may be remotely located. In another example, different computing systems may provide some or all of the processing, storage, and/or communication resources according to this disclosure.

It may be advantageous to set forth definitions of certain words and phrases used throughout this patent document. The term “couple” and its derivatives refer to any direct or indirect communication between two or more elements, whether or not those elements are in physical contact with one .another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “such as,” when used among terms, means that the latter recited term(s) is(are) example(s) and not limitation(s) of the earlier recited term. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described herein can be implemented or supported by one or more computer programs, each of which is formed from computer readable program code and embodied in a computer-readable medium. The terms “application” and “program” refer to one or more computer programs, software components, sets of instructions, procedures, functions, objects, classes, instances, related data, or a portion thereof adapted for implementation in a suitable computer readable program code. The phrase “computer-readable program code” includes any type of computer code, including source code, object code, and executable code. The phrase “computer-readable medium” includes any type of medium capable of being accessed by a computer, such as read-only memory (ROM), random access memory (RAM), a hard disk drive, a compact disc (CD), a digital video disc (DVD), or any other type of memory. A “non-transitory” computer-readable medium excludes wired, wireless, optical, or other communication links that transport transitory electrical or other signals. A non-transitory, computer-readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases. Although the present disclosure has been described with an exemplary embodiment, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claim scope. The scope of the patented subject matter is defined by the claims.

What is claimed is:

1. A system, comprising:
two or more chillers piped in series to cool a process cooling fluid,
wherein each chiller comprises a valve to direct a process cooling fluid to the chiller or to an air-cooled fluid cooler with an outlet of the chiller and an outlet of the air-cooled fluid cooler joined together.

2. The system of claim 1, wherein each of the two or more chillers comprise a combined fluid cooler and condenser assembly including a condenser surface coupled to a fluid cooler and multiple fans configured to pass cooling air through a surface of the condenser and the fluid cooler.

3. The system of claim 1, wherein each of the two or more chillers are configured to direct the process cooling fluid of each chiller stage away from the chiller and to a free cooling coil by based on a comparison of a required process cooling fluid temperature at the outlet of that stage to an ambient air temperature available to the fluid cooler.

4. The system of claim 1, further comprising:
one or more air handling units piped to the two or more chillers,
wherein each of the one or more air handling units comprise sections of coils having a number of sections equal to a number of chillers, and
wherein the sections of coils are arranged in series and wherein each section of coils is piped to a different chiller.

5. The system of claim 1, wherein
each of the two or more chillers comprises:
an economizer; and
a refrigeration compressor, and
each of the two or more chillers configured to divert the cooling fluid into the economizer and the refrigeration compressor.

6. The system of claim 1, wherein an air-cooled condenser coil of each of the two or more chillers and fluid cooler coil of each of the two or more chillers are combined in a single assembly including multiple fans that directs air from multiple fans through the fluid cooling coil and the air-cooled condenser coil in series.

7. A method to control capacity of chillers, the method comprising:
forming a cascade system by connecting a first chiller and a second chiller in series, wherein the first chiller comprises a first compressor and the second chiller comprises a second compressor; and
modulating a capacity of the first chiller, a capacity of the second chiller, or both to control a supply fluid temperature.

8. The method of control of claim 7, wherein modulating the capacity of the first chiller, the capacity of the second chiller, or both to control the supply fluid temperature comprises:
maintaining the supply fluid temperature by lowering the capacity of the first chiller in the cascade system when a modulating capacity of the second chiller reaches its minimum.

9. The method of control of claim 7, wherein the first chiller includes a first economizer and wherein the first chiller is configured to divert a cooling fluid into the first economizer and the first compressor.

10. The method of control of claim 9, wherein modulating the capacity of the first chiller, the capacity of the second chiller, or both to control the supply fluid temperature comprises:
turning off the first compressor when a combined capacity of a capacity of the first economizer and the capacity of the second chiller reaches a required capacity of the cascade system.

11. The method of control of claim 7, wherein:
the second chiller includes a second economizer, and
the second chiller is configured to divert a cooling fluid into the second economizer and the second compressor.

12. The method of control of claim 11, wherein modulating the capacity of the first chiller, the capacity of the second chiller, or both to control the supply fluid temperature comprises:
turning off the second compressor when a combined capacity of a capacity of the second economizer and the capacity of first chiller reaches a required capacity of the cascade system.

13. The method of control of claim 7, wherein modulating the capacity of the first chiller, the capacity of the second chiller, or both to control a required supply fluid temperature comprises:
modulating a cooling capacity of the first compressor, the second compressor, or both by varying their rotational speed.

14. The method of control of claim 13, wherein:
the first compressor, the second compressor, or both are screw compressors, and
modulating a cooling capacity of the first refrigeration compressor, the second compressor, or both comprises varying a position of an inlet valve to expose a swept area on an inlet side of the screw compressor.

15. A method to increase a supply cooling fluid temperature of a cascade chiller system, comprising:
monitoring positions of control valves on coils of air handlers close coupled connected to the cascade chiller system; and
increasing a supply cooling fluid temperature of the cascade chiller system as a function of an opening of at least one of the control valves.

16. The method of control of claim 15, wherein:
the cascade chiller system comprises a first chiller that includes a first economizer and a first compressor, and
increasing a supply cooling fluid temperature of the cascade chiller system comprises diverting the cooling fluid into the first economizer and the first compressor.

17. The method of control of claim 15, wherein:
the cascade chiller system comprises a second chiller that includes a second economizer and a second compressor, and
increasing a supply cooling fluid temperature of the cascade chiller system comprises diverting the cooling fluid into the second economizer and the second compressor.

18. The method of control of claim 15, wherein increasing the supply cooling fluid temperature of the cascade chiller system comprises:
modulating a cooling capacity of a refrigeration compressor of the cascade chiller system by varying their rotational speed.

19. The method of control of claim 18, wherein:
the refrigeration compressors are screw compressors, and
modulating a cooling capacity of the refrigeration compressors comprises varying a position of an inlet valve to expose a swept area on an inlet side of the screw compressors.

20. The method of control of claim 18, wherein:
each chiller of the cascade chiller system comprises a plurality of refrigeration compressors, and
a capacity of each chiller is modulated by switching one or more of the plurality of refrigeration compressors on or off.
